(19) United States
(12) Patent Application Publication
(10) Pub. No.: US 2025/0023552 A1
(43) Pub. Date: Jan. 16, 2025

(54) BULK ACOUSTIC WAVE FILTERS WITH DIFFERENTLY DOPED ALUMINUM NITRIDE RESONATORS

(71) Applicant: Skyworks Global Pte. Ltd., Singapore (SG)

(72) Inventors: Kwang Jae Shin, Yongin (KR); Alexandre Augusto Shirakawa, Cardiff by the Sea, CA (US); Yiliu Wang, Irvine, CA (US); Tetsuya Tsurunari, Hirakata-Shi (JP); Myung Hyun Park, Seongnam-si (KR); Nobufumi Matsuo, Suita-Shi (JP)

(21) Appl. No.: 18/770,441

(22) Filed: Jul. 11, 2024

Related U.S. Application Data
(60) Provisional application No. 63/526,519, filed on Jul. 13, 2023.

(51) Int. Cl. H03H 9/56; H03H 9/02; H03H 9/17; H03H 9/70

(52) U.S. Cl. CPC H03H 9/562; H03H 9/02031; H03H 9/173; H03H 9/176; H03H 9/564; H03H 9/568; H03H 9/706

(57) ABSTRACT

A wafer-level package module includes a first substrate having a first bulk acoustic wave (BAW) device mounted thereon with a first aluminum nitride piezoelectric layer. The wafer-level package module further includes a second substrate having a second BAW device mounted thereon with a second aluminum nitride piezoelectric layer. The first BAW device has a electromechanical coupling coefficient (kₜ²) different from the second BAW device.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field of the Disclosure

Some embodiments disclosed herein relate to acoustic wave devices, such as bulk acoustic wave devices, to wafer-level packages with multiple bulk acoustic wave devices, and to acoustic wave filters that include wafer-level packaged modules with multiple bulk acoustic wave devices.

### Description of the Related Art

Acoustic wave filters can be implemented in radio frequency electronic systems. For example, filters in a radio frequency front end of a mobile phone can include one or more acoustic wave filters. A plurality of acoustic wave filters can be arranged as a multiplexer. For instance, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. BAW filters can include BAW resonators. In BAW resonators, acoustic waves propagate in a bulk of a piezoelectric layer. Example BAW resonators include film bulk acoustic wave resonators (FBARs) and solidly mounted resonators (SMRs).

Acoustic wave filters employing BAW resonators are desired to have a passband that have low insertion losses (IL) at both frequency edges of the passband. However, measures that may be taken to lower the IL at one frequency edge of the passband may in some cases detrimentally affect the IL at the other frequency edge of the passband.

Although various acoustic wave filters equipped with BAW devices exist, there remains a need for acoustic wave filters that have better band edge characteristics.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

In accordance with one aspect of the disclosure, a wafer-level package module includes a first substrate having a first bulk acoustic wave (BAW) device mounted thereon. The first BAW device includes a first electrode, a second electrode, and a first aluminum nitride piezoelectric layer between the first electrode and the second electrode. The wafer-level package module further includes a second substrate having a second BAW device mounted thereon. The second BAW device includes a third electrode, a fourth electrode, and a second aluminum nitride piezoelectric layer between the third electrode and the fourth electrode. The first BAW device having a electromechanical coupling coefficient (kₜ²) different from an electromechanical coupling coefficient (kₜ²) of the second BAW device.

The first aluminum nitride piezoelectric layer can be doped with a dopant selected from the group of scandium (Sc), yttrium (Y), hafnium (Hf), zirconium (Zr), tantalum (Ta), magnesium (Mg), niobium (Nb), silicon (Si), and chromium (Cr). In some embodiments, the second aluminum nitride piezoelectric layer can be pure aluminum nitride. In other embodiments, the second aluminum nitride piezoelectric layer can be doped with a dopant selected from the group of boron (B), titanium (Ti), gallium (Ga), calcium (Ca), and vanadium (V). In several embodiments, the first aluminum nitride piezoelectric layer can be pure aluminum nitride.

The first substrate and the second substrate can be interconnected with through-level vias (TLVs). In various embodiments, the first BAW device can be mounted on a first surface of the first substrate and the second BAW device can be mounted on a first surface of the second substrate. In some implementations, the first surface of the first substrate can be facing the first surface of the second substrate.

In a number of embodiments, the WLP module can further comprise a third BAW device mounted on the first substrate. The third BAW device can include a fifth electrode, a sixth electrode, and a third aluminum nitride piezoelectric layer between the fifth electrode and the sixth electrode. The third BAW device can have substantially the same electromechanical coupling coefficient (kₜ²) as the first BAW device, that is a value of the electromechanical coupling coefficient (kₜ²) which is within a +/−20% range of the electromechanical coupling coefficient (kₜ²) of the first BAW device. In several embodiments, the first aluminum nitride piezoelectric layer and the third aluminum nitride piezoelectric layer can both include pure aluminum nitride. The second aluminum nitride piezoelectric layer can be doped with a dopant selected from the group of boron (B), titanium (Ti), gallium (Ga), calcium (Ca), and vanadium (V). In other embodiments, the first aluminum nitride piezoelectric layer and the third aluminum nitride piezoelectric layer can be doped with a dopant selected from the group of scandium (Sc), yttrium (Y), hafnium (Hf), zirconium (Zr), tantalum (Ta), magnesium (Mg), niobium (Nb), silicon (Si), and chromium (Cr). The second aluminum nitride piezoelectric layer can be doped with a dopant selected from the group of boron (B), titanium (Ti), gallium (Ga), calcium (Ca), and vanadium (V). Alternatively, the second aluminum nitride piezoelectric layer can be pure aluminum nitride.

According to various embodiments, the WLP module can further comprise a fourth BAW device mounted on the second substrate. The fourth BAW device can include a seventh electrode, an eighth electrode, and a fourth aluminum nitride piezoelectric layer between the seventh electrode and the eighth electrode. The fourth BAW device can have the substantially the same electromechanical coupling coefficient (kₜ²) as the second BAW device, that is a value of the electromechanical coupling coefficient (kₜ²) which is within a +/−20% range of the electromechanical coupling coefficient (kₜ²) of the second BAW device. In a few embodiments thereof, the second aluminum nitride piezoelectric layer and the fourth aluminum nitride piezoelectric layer can be doped with a dopant selected from the group of boron (B), titanium (Ti), gallium (Ga), calcium (Ca), and vanadium (V).

In accordance with one aspect of the disclosure, an acoustic wave filter includes a wafer-level package (WLP) module. The WLP module includes a first substrate having a first bulk acoustic wave (BAW) resonator mounted thereon. The first BAW resonator includes a first electrode, a second electrode, and a first aluminum nitride piezoelectric layer between the first electrode and the second electrode. The wafer-level package module further includes a second substrate having a second BAW resonator mounted thereon. The second BAW resonator includes a third electrode, a fourth electrode, and a second aluminum nitride piezoelectric layer between the third electrode and the fourth electrode. The first BAW resonator has a electromechanical coupling coefficient (kₜ²) different from an electromechanical coupling coefficient (kₜ²) of the second BAW resonator.

The first BAW resonator and the second BAW resonator can be electrically coupled in parallel or in series. In a number of embodiments, the acoustic wave filter can be a ladder type filter, a hybrid-ladder type filter, or a lattice type filter. In several embodiments, the acoustic wave filter further includes a third BAW resonator mounted on the first substrate. The third BAW resonator can include a fifth electrode, a sixth electrode, and a third aluminum nitride piezoelectric layer between the fifth electrode and the sixth electrode. The third BAW resonator can have the same electromechanical coupling coefficient (kₜ²) as the first BAW resonator.

In various embodiments, the acoustic wave filter further includes a fourth BAW resonator mounted on the second substrate. The fourth BAW resonator includes a seventh electrode, an eighth electrode, and a fourth aluminum nitride piezoelectric layer between the seventh electrode and the eighth electrode. The fourth BAW resonator substantially the same electromechanical coupling coefficient (kₜ²) as the second BAW resonator, that is a value of the electromechanical coupling coefficient (kₜ²) which is within a +/−20% range of the electromechanical coupling coefficient (kₜ²) of the second BAW resonator. In some embodiments, the first BAW resonator, the second BAW resonator, the third BAW resonator, and the fourth BAW resonator can be connected in a quad filter.

A filter can include one or more of the bulk acoustic wave devices disclosed herein. The filter can be at least one of a band pass filter, a band stop filter, a ladder filter, and a lattice filter. A filter that includes one or more bulk acoustic wave devices disclosed herein can form part of at least one of a diplexer, a duplexer, a multiplexer, and a switching multiplexer. A radio frequency module can include an acoustic wave die with at least one filter that has one or more of the bulk acoustic wave devices disclosed herein, and a radio frequency circuit clement coupled to the acoustic wave die. The acoustic wave die and the radio frequency circuit element can be enclosed within a common module package. A wireless communication device can include an acoustic wave filter including one or more of the bulk acoustic wave devices disclosed herein, an antenna operatively coupled to the acoustic wave filter, a radio frequency amplifier operatively coupled to the acoustic wave filter and configured to amplify a radio frequency signal, and a transceiver in communication with the radio frequency amplifier. The wireless communication device can include a baseband processor in communication with the transceiver. The acoustic wave filter can be included in a radio frequency front end. The wireless communication device can be user equipment.

In accordance with one aspect of the disclosure, a duplexer includes a wafer-level package (WLP) module. The WLP module includes a first substrate having a first bulk acoustic wave (BAW) resonator mounted thereon. The first BAW resonator includes a first electrode, a second electrode, and a first aluminum nitride piezoelectric layer between the first electrode and the second electrode. The WLP module further includes a second substrate having a second BAW resonator mounted thereon. The second BAW resonator includes a third electrode, a fourth electrode, and a second aluminum nitride piezoelectric layer between the third electrode and the fourth electrode. The first BAW resonator has a electromechanical coupling coefficient (kₜ²) different from an electromechanical coupling coefficient (kₜ²) of the second BAW resonator.

The first BAW resonator can be a series resonator. The second BAW resonator can be a shunt resonator. The second BAW resonator can have an electromechanical coupling coefficient (kₜ²) that is larger than the electromechanical coupling coefficient (kₜ²) of a first BAW resonator. According to various embodiments, the first aluminum nitride piezoelectric layer of the first BAW resonator can be made from pure aluminum nitride. In some alternative embodiments, the first aluminum nitride piezoelectric layer of the first BAW resonator can be doped with a dopant selected from the group of boron (B), titanium (Ti), gallium (Ga), calcium (Ca), and vanadium (V). In a few embodiments, the second aluminum nitride piezoelectric layer of the second BAW resonator can be doped with a dopant selected from the group of scandium (Sc), yttrium (Y), hafnium (Hf), zirconium (Zr), tantalum (Ta), magnesium (Mg), niobium (Nb), silicon (Si), and chromium (Cr).

In accordance with one aspect of the disclosure, a method of manufacturing a wafer-level package (WLP) module involves mounting a first bulk acoustic wave (BAW) device on a first substrate, the first BAW device including a first electrode, a second electrode, and a first aluminum nitride piezoelectric layer between the first electrode and the second electrode. The method further involves mounting a second BAW device on a second substrate, the second BAW device including a third electrode, a fourth electrode, and a second aluminum nitride piezoelectric layer between the third electrode and the fourth electrode. The first BAW device has an electromechanical coupling coefficient (kₜ²) different from an electromechanical coupling coefficient (kₜ²) of the second BAW device. The method further involves stacking the first substrate and the second substrate to form a WLP module.

### BRIEF DESCRIPTION OF THE DRAWINGS

Embodiments of this disclosure will now be described, by way of non-limiting example, with reference to the accompanying drawings, like reference numerals can refer to similar features throughout.

FIG. 1 is a plan view of an example embodiment of a bulk acoustic wave device.

FIG. 2 is a cross-sectional view of an example embodiment of a suspended frame bulk acoustic wave device.

FIG. 3 is a cross-sectional view of an example embodiment of a raised and recessed frame bulk acoustic wave device.

FIG. 4 is a cross-sectional view of an example embodiment of a suspended frame bulk acoustic wave device.

FIG. 5 is a cross-sectional view of another example embodiment of a bulk acoustic wave device on a Bragg reflector.

FIG. 6 is a cross-sectional view of an example embodiment of a wafer-level package having multiple bulk acoustic wave devices.

FIG. 7 is a cross-sectional view of another example embodiment of a wafer-level package having multiple bulk acoustic wave devices.

FIGS. 8A-8E are schematic diagrams of examples of acoustic wave ladder filters.

FIG. 9 is a schematic diagram of an example of a duplexer.

FIG. 10 is a schematic diagram of an example of a multiplexer.

FIG. 11 is a schematic block diagram of a module that includes an antenna switch and duplexers that include one or more raised frame bulk acoustic wave devices.

FIG. 12A is a schematic block diagram of a module that includes a power amplifier, a radio frequency switch, and duplexers that include one or more raised frame bulk acoustic wave devices.

FIG. 12B is a schematic block diagram of a module that includes a low noise amplifier, a radio frequency switch, and acoustic wave filters to include one or more raised frame bulk acoustic wave devices.

FIG. 13 is a schematic block diagram of a module that includes a power amplifier, a radio frequency switch, a duplexer that includes one or more raised frame bulk acoustic wave devices.

FIG. 14A is a schematic block diagram of a wireless communication device that includes filters that include one or more raised frame bulk acoustic wave devices.

FIG. 14B is a schematic block diagram of another wireless communication device that includes filters that include one or more raised frame bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The positions and directions described herein may be described in relation to the orientations illustrated in the Figures, and in some cases the illustrated devices could be positioned in different orientations during use. For example, in some instances a substrate is shown at the bottom of a device, and the substrate could still be considered the bottom of the device even if it were installed in an inverted configuration.

For developing high performance bulk acoustic wave (BAW) filters, a high quality factor (Q) can be generally desirable. Bulk acoustic wave (BAW) devices can include raised/recessed and/or suspended frame structures. A raised/recessed and/or suspended frame structure can reduce lateral energy leakage from a main acoustically active region of the bulk acoustic wave device. A BAW device can include a single-layer raised frame structure, in some implementations. A BAW device can include a multi-layer raised frame structure, in some implementations. A BAW device can include a raised frame structure having a layer that includes a material with a relatively low acoustic impedance (e.g., lower than one or both of the electrodes and/or the piezoelectric layer), such as silicon dioxide. A BAW device can include a gap (e.g., filled with air) under a raised frame structure such that at least a portion of the raised frame structure is a suspended frame. The suspended frame structure of the BAW device can facilitate achieving a relatively high Q (in some cases, for a region above a resonant frequency and/or an anti-resonant frequency). BAW devices with the raised and/or suspended frame structures disclosed herein can achieve low insertion loss and/or low Gamma loss, in some cases.

BAW devices with the raised/recessed and/or suspended frame structures disclosed herein can achieve a relatively high electromechanical coupling coefficient (kₜ²), in some cases, which can be desirable for certain applications, such as for relatively wide pass band filters. An appropriate electromechanical coupling coefficient (kₜ²) for BAW devices that can be effectively used in filter applications for radio communication may also be adjusted by different dopants and/or dopant concentrations of an AlN based piezoelectric layer of a BAW device.

Some aspects of this disclosure relate to a wafer-level package (WLP) module of bulk acoustic wave (BAW) resonators on different substrates that includes differently doped AlN based piezoelectric layer for BAW resonators on opposite substrates of the WLP module, as discussed herein. The variations in dopant choice and/or dopant concentration of the AlN based piezoelectric layer enables tuning of kₜ² values of the BAW resonators to different values. Thereby, tuning the kₜ² values of the BAW resonators gives the opportunity to improve the insertion loss (IL) of different BAW resonators at frequency edges of the passband where it matters most. For example, in case of narrow guard band duplexer filters, BAW resonators employed as series resonators may be tuned towards a lower kₜ² value while shunt resonators may be tuned to towards a higher kₜ² value. In turn, the IL of the BAW resonators employed as series resonators are improved at the high frequency edge of their passband while the IL of the BAW resonators employed as shunt resonators are improved at the low frequency edge of their passband.

BAW resonators with differently doped AlN based piezoelectric layers may be manufactured on separate substrates and then combined in a wafer-level package (WLP). Dopants for the AlN based piezoelectric layers may be elements such as scandium (Sc), yttrium (Y), hafnium (Hf), zirconium (Zr), tantalum (Ta), magnesium (Mg), niobium (Nb), silicon (Si), chromium (Cr), boron (B), titanium (Ti), gallium (Ga), calcium (Ca), and vanadium (V). Of those dopants, Sc, Y, Hf, Zr, Ta, Mg, Nb, Si, and Cr are generally used as dopants to increase the kₜ² value while B, Ti, Ga, Ca, and V as dopants to decrease the kₜ² value.

The WLP modules may be interconnected and/or stacked with through-level vias (TLVs). The WLP modules with BAW resonators having differently doped AlN based piezoelectric layers may be employed in ladder type, hybrid-ladder type, and lattice type acoustic wave filters. Moreover, the acoustic wave filters employing WLP modules with BAW resonators having differently doped AlN based piezoelectric layers may be implemented as transmission (Tx), reception (Rx), or duplexer filters.

Although some embodiments disclosed herein may be discussed with reference to single raised frame structures with a single layer, such as of the low acoustic impedance material, various suitable principles and advantages discussed herein can be applied to a multi-layer raised frame structure that includes two or three or more raised frame layers. For example, in some cases a first raised frame layer can include a relatively low acoustic impedance material, whereas a second raised frame layer can include a relatively high acoustic impedance material. The second raised frame layer can include a material this is heavier or denser than the material of the first raised frame layer. In some cases, the second raised frame layer can be the same material as an electrode of the bulk acoustic wave resonator. The suspended frame can include a gap, such as below the first and second raised frame layers.

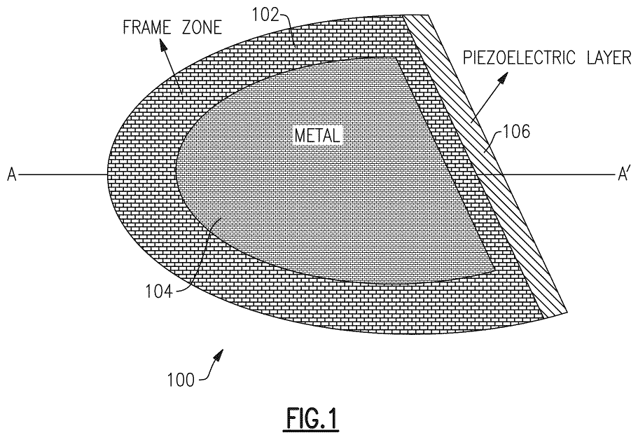

FIG. 1 is a plan view of a raised frame bulk acoustic wave (BAW) device 100. As shown in FIG. 1, the bulk acoustic wave device 100 can include a frame zone 102 around the perimeter of an active region of the bulk acoustic wave device 100. The frame zone 102 can be referred to as a border ring in certain instances. A suspended frame structure and/or raised/recessed frame structure can be in the frame zone 102. The raised/recessed and/or suspended frame structures can be implemented in accordance with any suitable principles and advantages disclosed herein. The frame zone 102 can be outside of a middle area 104 of the active region of the bulk acoustic wave device 100. One or more raised frame layers and/or a gap can be in the frame zone 102 and can extend above a metal electrode. FIG. 1 illustrates the metal electrode at the middle area 104 and the raised frame layer at the frame zone 102. One or more other layers can be included over the metal electrode and the raised frame layer. For instance, silicon dioxide can be included over the metal electrode and the raised frame layer. FIG. 1 also illustrates that a piezoelectric layer 106 of the bulk acoustic wave device 100 can be below the metal electrode and the raised frame layer.

Some embodiments of raised frame bulk acoustic wave devices will be discussed with reference to example cross sections along the line from A to A′ in FIG. 1. Any suitable combination of features of the bulk acoustic wave devices disclosed herein can be combined with each other. Any of the bulk acoustic wave devices disclosed herein can be a bulk acoustic wave resonator in a filter, such as arranged to filter a radio frequency signal.

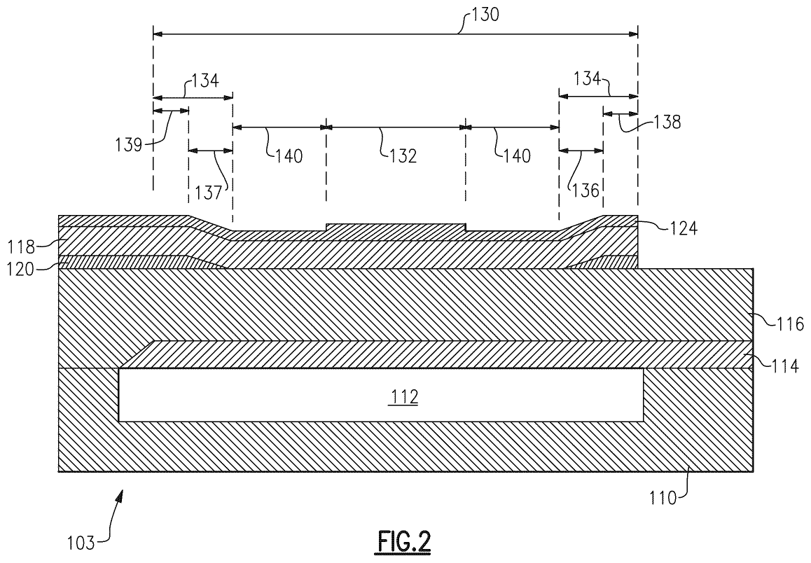

FIG. 2 is a schematic cross-sectional view of an example bulk acoustic wave (BAW) device 103 with a raised frame structure. The BAW device 103 can include a support substrate 110, a cavity 112 (e.g., a reflector cavity), a first or lower electrode 114 positioned over the support substrate 110, a piezoelectric layer 116 positioned over the lower electrode 114, a second or upper electrode 118 positioned over the piezoelectric layer 116, a raised frame structure or layer 120 positioned at least partially between the piezoelectric layer 116 and the upper electrode 118, and a passivation layer 124 positioned over the upper electrode 118.

The support substrate 110 can be a silicon substrate, and other suitable substrates can alternatively be implemented in place of the silicon substrate. One or more layers, such as a passivation layer, can be positioned between the lower electrode 114 and the support substrate 110. In some embodiments, the cavity 112 can be an air cavity.

The piezoelectric layer 116 can be disposed between the first electrode 114 and the second electrode 118. The piezoelectric layer 116 can be an aluminum nitride (AlN) piezoelectric layer. An active region 130 or active domain of the BAW device 100 can be defined by the portion of the piezoelectric layer 116 that overlaps with both the lower electrode 114 and the upper electrode 118, for example over an acoustic reflector, such as the cavity 112. The lower electrode 114 and/or the upper electrode 118 can have a relatively high acoustic impedance. For example, the lower electrode 114 and/or the upper electrode 118 can include molybdenum (Mo), tungsten (W), ruthenium (Ru), iridium (Ir), platinum (Pt), an alloy that include Ir and Pt, or any suitable alloy and/or combination of any of these materials, although other suitable conductive materials could be used. The upper electrode 118 can be formed of the same material as the lower electrode 114 in certain instances, although different materials can be used for the lower electrode 114 and the upper electrode 118, in some cases.

The illustrated BAW device 100 can include an active region 130 that has a main acoustically active region 132 and a raised frame region 134 at least partially, or fully, surrounding the main acoustically active region 132 (e.g., in plan view). In the cross-sectional view of FIG. 2, the raised frame region 134 can be on opposing sides of the main acoustically active region 132. The main acoustically active region 132 may be referred to as a center region or middle area of the active region 130. The main acoustically active region 132 can set the main resonant frequency of the BAW device 100. There can be a significant (e.g., exponential) drop of acoustic energy in the piezoelectric layer 116 for a main mode in the raised frame region 134 relative to the main acoustically active region 132. A recessed frame region 140 can be positioned between the main acoustically active region 132 and the raised frame region 134.

The raised frame layer 120 can be positioned between the first or lower electrode 114 and the second or upper electrode 118. As illustrated in FIG. 2, the raised frame layer 120 can be positioned between the piezoelectric layer 116 and the second electrode 118. The raised frame layer 120 can extend beyond the active region 130 of the bulk acoustic wave device 100 as shown in FIG. 2, which can be beneficial for manufacturability reasons in certain instances.

The raised frame layer 120 can be a low acoustic impedance material. The low acoustic impedance material can have a lower acoustic impedance than the material of the first electrode 114. The low acoustic impedance material has a lower acoustic impedance than the material of the second electrode 118. The low acoustic impedance material can have a lower acoustic impedance than the material of the piezoelectric layer 116. As an example, the raised frame layer 120 can be a silicon dioxide (SiO2) layer. Other oxide materials can be used, and the raised frame structure or layer 120 can be an oxide raised frame structure or layer. The raised frame layer 120 can be a silicon nitride (SiN) layer, a silicon carbide (SiC) layer, or any other suitable low acoustic impedance layer. The raised frame layer 120 can have a relatively low density. The density and/or acoustic impedance of the raised frame layer 120 can be lower than the density and/or acoustic impedance of the lower electrode 114, of the upper electrode 118, and/or of the piezoelectric layer 116 of the BAW device 100.

In some implementations, the BAW device 100 can have a gap (e.g., a cavity or recess) under at least a portion of the raised frame structure. The gap can be formed between the raised frame layer 120 and the piezoelectric layer 116. The gap can be filled with air, in some embodiments, although it can contain any suitable material. The gap can be an air gap or cavity. The gap can be a void. The gap can be formed using a sacrificial layer, such as using polysilicon, or any other suitable material that can be removed during the manufacturing process to create the gap. The gap can suspend the above-lying layers. The gap can elevate one or more layers to at least partially define the raised frame structure 134.

The passivation layer 124 can be positioned over the upper electrode 118, and/or over the raised frame layer 120, and/or over the gap, if any. The passivation layer 124 can be a silicon dioxide layer, although any suitable passivation material can be used. The passivation layer 124 can be formed with different thicknesses in different regions of the BAW device 100. For example, as shown in FIG. 2, the passivation layer 124 can be thinner in the recessed frame region 140 than in the main acoustically active region 132, or than in other portions such as the raised frame region 134. In some cases, the recessed frame region 140 can contribute to achieving the relatively high Q, such as below the resonant frequency. By way of example, the combination of the recessed frame region 140 and the raised frame structure of the BAW device 100 can contribute to achieving the relatively high Q, such as below the resonant frequency. In some embodiments, the recessed frame region 140 can be omitted, such as by using a passivation layer 124 that has a substantially uniform thickness. Also, in some embodiments, the passivation layer 124 can be omitted.

A gradient portion of the raised frame structure can have an angle with respect to a horizontal direction. The angle can be with respect to an underlying layer (e.g., a piezoelectric layer). The gradient portion of the raised frame layer 120 or overlying layer(s) can have an upper surface that is angled (e.g., downward or towards the piezoelectric layer 116 or lower electrode 114) by an angle. The gradient angle of the raised frame layer 120 can affect the layers above the raised frame layer 120. The gap can also have a gradient portion that has the gradient angle, which can similarly affect the overlying layer(s). The gradient portion 136, 137 of the inner raised frame portion 134 can have the gradient angle. The upper electrode 118 and/or the passivation layer 124 can also have the gradient angle. The gradient angle can be less than 90° or less than about 40°, in some embodiments. In some cases, the taper angle can be about 5°, about 10°, about 15°, about 20°, about 30°, about 45°, about 60°, about 75°, or any values therebetween, or any ranges between any of these values. For example, in some instances, the angle can be in a range from about 10° to about 30° for a gradient portion of a raised frame portion in a gradient region, or for other associated layers. In some embodiments, the gradient angle can vary along the length of the associated gradient portion. For example, a gradient portion can start with a smaller angle and can transition to a larger angle. In some cases, the gradient portion can have curvature.

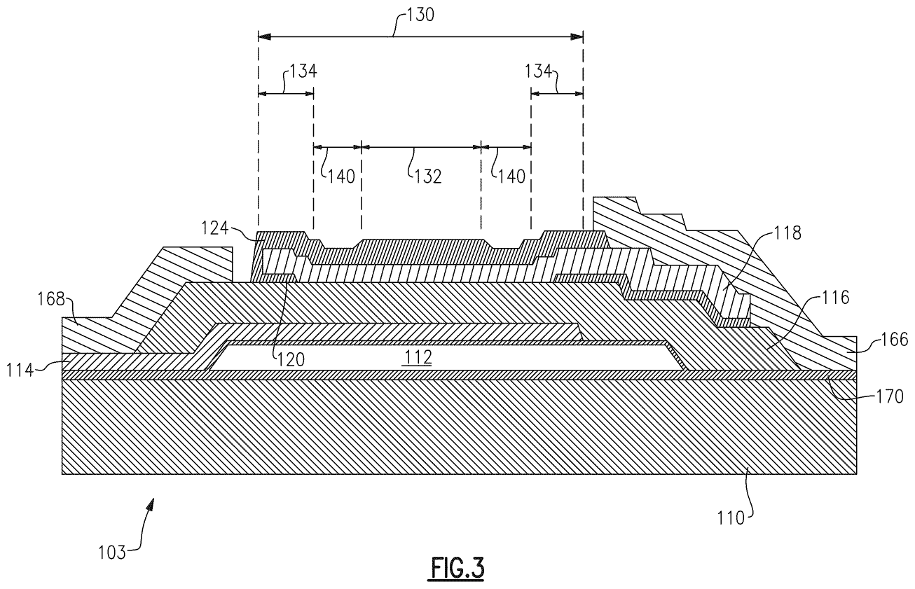

FIG. 3 shows a cross-sectional view of a BAW device 103, which can be similar to the BAW device 103 of FIG. 2, except as discussed herein. The BAW device 103 can include a support substrate 110, a cavity 112 (e.g., a reflector cavity), a first or lower electrode 114 positioned over the support substrate 110, a piezoelectric layer 116 positioned over the lower electrode 114, a second or upper electrode 118 positioned over the piezoelectric layer 116, a raised frame structure or layer 120 positioned at least partially between the piezoelectric layer 116 and the upper electrode 118, and a passivation layer 124 positioned over the upper electrode 118. In some implementations, the BAW device 103 can further include a gap (e.g., a cavity) between the piezoelectric layer 116 and the raised frame layer 120.

The BAW device 103 can have an active region 130 or active domain, which can be defined by the portion of the piezoelectric layer 116 that overlaps with both the lower electrode 114 and the upper electrode 118. A main acoustically active region 132 may be at a center region or middle area of the active region 130. A recessed frame region 140 can be disposed outward of the main acoustically active region 132. A raised frame region 134 or structure can be disposed outward of the recessed frame region 140.

In some embodiments, the piezoelectric layer 116 can have a step (e.g., which can be defined by the piezoelectric layer 116 stepping up to be disposed over the lower electrode 114. The gap can include a step that corresponds to the step in the piezoelectric layer 116. At least part of an upper portion of the gap be disposed above the lower electrode 114, and at least part of the lower portion of the gap is not disposed over the lower electrode 114. The lower portion of the gap can extend outward past and end of the lower electrode 114.

In some embodiments, a first conductive layer 166 can be disposed over at least a portion of the passivation layer 124. The passivation layer 124 can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap, although other locations could also be used. The conductive layer 166 can contact the upper electrode 118, can extend through the opening in the passivation layer 124, and/or can extend outward from the opening (e.g., above the passivation layer 124). Electrical signals and/or electrical power can be delivered to and/or from the upper electrode 118 through the first conductive layer. The opening or electrical contact between the first conductive layer 166 and the upper electrode 118 can be disposed directly above the lower electrode 114, the piezoelectric layer 116, the upper electrode 118, a portion of the gap, and/or a portion of the raised frame layer 120. In some embodiments, the active region 130 can omit the area covered by the first conductive layer 166, as shown in FIG. 3, even if that area includes overlapping of the piezoelectric layer 116, the lower electrode 114, and the upper electrode 118.

In some embodiments, a second conductive layer 168 can be disposed over a portion of the lower electrode 114. For example, a portion of the lower electrode 114 can extend outward past an end of the piezoelectric layer 116 (e.g., on the right side of FIG. 3). The second conductive layer 168 can be positioned over (e.g., in direct contact with) that portion of the lower electrode 114. The second conductive layer 168 can provide electrical signals and/or electrical power to and/or from the lower electrode 114. In some embodiments, either or both of the first conductive layer 166 and the second conductive layer 168 can be omitted. For example, electrical signals can be delivered directly to or from either or both of the electrodes 114, 118, in some implementations.

The first conductive layer 166 and/or the second conductive layer 168 can be made of a material that has higher electrical conductivity than the upper electrode 118 or the lower electrode 114. For example, the first conductive layer 166 and/or the second conductive layer 168 can be made from gold or another conductive metal (e.g., copper or aluminum). In some embodiments, a material for the upper electrode 118 and/or the lower electrode 114 can have a relatively high acoustic impedance even if the electrical conductivity is not optimal. In some embodiments, the upper electrode 118 and/or the lower electrode 114 can include a material with higher acoustic impedance and/or lower electrical conductivity than the material of the first conductive layer 166 and/or the second conductive layer 168. The first conductive layer 166 and/or the second conductive layer 168 can have less effect on the acoustic vibrations, as compared to a BAW device that uses the relatively high acoustic impedance material of the electrode(s) 114, 118 to deliver electrical signals. The conductive layer 166 can be disposed above the gap, and the gap can insulate the conductive layer 166 from vibrations. Also, the first conductive layer 166 and/or the second conductive layer 168 can reduce ohmic loss, as compared to a BAW device that uses the lower conductivity material of the electrode(s) 114, 118 to deliver electrical signals. The BAW device 103 of FIG. 2, and other embodiments disclosed herein, can include the first conductive layer 166 and/or the second conductive layer 168, similar to the BAW device 103 of FIG. 3.

As shown in FIG. 2, the cavity 112 can be a recess formed in the substrate 110. The lower electrode 114 can extend along a plane from the connection with the second conductive layer 168. As shown in FIG. 3, in some embodiments, the cavity 112 can be formed above the substrate 110. The top surface of the substrate 110 can be planar. The lower electrode 114 and/or the piezoelectric layer 116 can include a step, with a lower region (e.g., which can be next to the cavity 112) and an upper region (e.g., which can be above the cavity 112).

As shown in FIG. 3, in some embodiments, the BAW device 103 can include an oxide layer 170 (e.g., silicon dioxide) between the substrate 110 and the lower electrode 114. The oxide layer 170 can partially or completely surround the cavity 112. The other BAW devices disclosed herein can include the oxide layer 170. In some embodiments, the oxide layer 170 can be omitted.

The BAW device designs disclosed herein can have improved performance, such as by improving the Q value, improving the kₜ² value, and/or reducing the spurious mode. The BAW device designs disclosed herein can have aluminum nitride (AlN) piezoelectric layers 116 that are doped with different dopants. Dopants for the AlN piezoelectric layers 116 may be elements selected from the group of scandium (Sc), yttrium (Y), hafnium (Hf), zirconium (Zr), tantalum (Ta), magnesium (Mg), niobium (Nb), silicon (Si), chromium (Cr), boron (B), titanium (Ti), gallium (Ga), calcium (Ca) and vanadium (V). BAW devices having AlN piezoelectric layers 116 that are doped with one or more of the group of Sc, Y, Hf, Zr, Ta, Mg, Nb, Si, and Cr yield increased kₜ² values. BAW devices having AlN piezoelectric layers 116 that are doped with one or more of the group of B, Ti, Ga, Ca, and V yield decreased kₜ² values.

The BAW device can be a film bulk acoustic wave resonator (FBAR), as illustrated in FIGS. 2 and 3. A cavity 112 can be included, such as below the first or lower electrode 114. The cavity 112 can be filled with air, in some implementations. The cavity 112 can be defined by the geometry of the first electrode 114 and/or the substrate 110. The cavity 112 can be an acoustic reflector cavity. The cavity 112 can be separate from the gap 122 disclosed herein. The cavity 112 can be disposed below the lower electrode 114. The gap 122 can be disposed above a lower surface of the lower electrode 114, above the lower electrode 114, and/or above the piezoelectric layer 116.

FIG. 4 shows a cross-sectional view of a BAW device 105, which can be similar to the BAW device 103 of FIG. 3, except as discussed herein. The BAW device 105 can include a support substrate 110, a cavity 112 (e.g., a reflector cavity), a first or lower electrode 114 positioned over the support substrate 110, a piezoelectric layer 116 positioned over the lower electrode 114, a second or upper electrode 118 positioned over the piezoelectric layer 116, a raised frame structure or layer 120 positioned at least partially between the piezoelectric layer 116 and the upper electrode 118, a gap (e.g., a cavity) between the piezoelectric layer 116 and the raised frame layer 120, and a passivation layer 124 positioned over the upper electrode 118.

The BAW device 105 can have an active region 130 or active domain, which can be defined by the portion of the piezoelectric layer 116 that overlaps with both the lower electrode 114 and the upper electrode 118. A main acoustically active region 132 may be at a center region or middle area of the active region 130. A recessed frame region 140 can be disposed outward of the main acoustically active region 132. A raised frame region 134 or structure can be disposed outward of the recessed frame region 140. The raised frame region 134 can include a first raised frame portion 134a, a second raised frame portion 134b, which can be disposed outward of the first raised frame portion, and a suspended frame portion 134c, which can be disposed outward of the second raised frame portion 134b. The first raised frame portion 134a can have a first height, and the second raised frame portion 134b can have a second height that is larger than the first height. The raised frame layer 120 can abut against the piezoelectric layer 116 along a first area across a first width 109, and the raised frame layer 120 can step up to form a gap 107 between the raised frame layer 120 and the piezoelectric layer 116 along a second area across a second width 111. The second area can be disposed outward of the first area. In some embodiments, the height of the first raised frame portion 134a can be substantially the same as a thickness of the raised frame layer 120 (e.g., at least at the first area that abuts against the piezoelectric layer 116). The first raised frame portion 134a can be produced by at least the upper electrode 118 stepping up and being elevated by the raised frame layer 120 (e.g., the first raised frame portion 134a can extend along the first area of the raised frame layer 120).

In some embodiments, the height of the second raised frame portion 134b can be substantially the same as the combined thickness of the gap 107 and the raised frame layer 120 (e.g., at least at the second area above the gap 107). The difference in height of the second raised frame portion 134b and the first raised frame portion 143a can be substantially the same as the thickness of the gap 107. The second raised frame portion 134b can be produced by at least the upper electrode 118 stepping up and being elevated by the raised frame layer 120 (e.g., the second area thereof) and the gap 107. The suspended frame portion 134c can have the same height as the second raised frame portion 134b, in some embodiments. The suspended frame portion 134c can be the portion of the raised frame structure 134 that is directly above the gap 107. The second raised frame portion 134b can be the portion of the raised frame structure 134 that is elevated above the first raised frame portion 134a (e.g., by the gap 107), but is not directly above the gap 107, such as due to the thickness of the material at the gradient portions or angled steps of the layer(s). In some embodiments, the suspended frame portion 134c can be considered a portion of the second raised frame portion 134b that is positioned above the gap 107. In some configurations, the full second raised frame portion can be disposed above the gap 107, so that the second raised frame portion is also the suspended frame portion. In some embodiments, the raised frame region 134 can include a suspended frame portion 134c that corresponds to the portion of the raised frame structure that is directly above the gap 107, or that is suspended over the gap 107. The suspended frame portion 134c can correspond to the second area of the raised frame layer 120, which is spaced apart from the piezoelectric layer 116 by the gap 107. The second raised frame portion 134b can correspond to the first area of the raised frame layer 120, which can abut against the piezoelectric layer 116, or is otherwise not be above the gap 107. The first raised frame portion 134a can correspond to an area of the upper electrode 118 that is elevated by the raised frame layer 120. In some embodiments, a portion of the elevated upper electrode 118 can be disposed inward from the raised frame layer 120, such as because of the thickness of the material at the gradient portion or angled step. In some embodiments, the piezoelectric layer 116 can have a step (e.g., which can be defined by the piezoelectric layer 116 stepping up to be disposed over the lower electrode 114. The gap 107 can include a step that corresponds to the step in the piezoelectric layer 116. At least part of an upper portion of the gap 107 be disposed above the lower electrode 114, and at least part of the lower portion of the gap 107 is not disposed over the lower electrode 114. The lower portion of the gap 107 can extend outward past and end of the lower electrode 114. The step can be between the upper and lower portions of the gap 107, as shown on the left of FIG. 4. In some embodiments, the step in the gap 107 can be omitted. In some embodiments, the suspended frame can be larger on one side than the other side. In some embodiments, the upper electrode 118 can extend over the step in the gap 107. In some embodiments, the active area 130 can extend over the step in the gap 107. In some configurations, the gap portions (e.g., at least the portions of the gap portions that overlap the active area 130) can be asymmetrical, or they can be substantially symmetrical, as discussed herein. In some embodiments, a portion of the gap 107 can be open. The passivation layer 124 can extend across one or both ends of the upper electrode 118 and can meet with the raised frame layer 120 that is disposed below the upper electrode 118. In some embodiments, the raised frame layer 120 and the passivation layer 124 can be made of the same material (e.g., silicon dioxide or other oxide material). The raised frame layer 120 and/or the passivation layer 124 can extend down to the piezoelectric layer 116 (or other underlying layer) at a location that is outward of the gap, which can close at least a portion of the gap.

In some embodiments, a first conductive layer 166 can be disposed over at least a portion of the passivation layer 124. The passivation layer 124 can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap, although other locations could also be used. The conductive layer 166 can contact the upper electrode 118, can extend through the opening in the passivation layer 124, and/or can extend outward from the opening (e.g., above the passivation layer 124). Electrical signals and/or electrical power can be delivered to and/or from the upper electrode 118 through the first conductive layer. The opening or electrical contact between the first conductive layer 166 and the upper electrode 118 can be disposed directly above the lower electrode 114, the piezoelectric layer 116, the upper electrode 118, a portion of the gap, and/or a portion of the raised frame layer 120. In some embodiments, the active region 130 can omit the area covered by the first conductive layer 166, even if that area includes overlapping of the piezoelectric layer 116, the lower electrode 114, and the upper electrode 118. In some embodiments, a second conductive layer 168 can be disposed over a portion of the lower electrode 114. For example, a portion of the lower electrode 114 can extend outward past an end of the piezoelectric layer 116 (e.g., on the right side of FIG. 4). The second conductive layer 168 can be positioned over (e.g., in direct contact with) that portion of the lower electrode 114. The second conductive layer 168 can be provide electrical signals and/or electrical power to and/or from the lower electrode 168. In some embodiments, either or both of the first conductive layer 166 and the second conductive layer 168 can be omitted. For example, electrical signals can be delivered directly to or from either or both of the electrodes 114, 118, in some implementations. The first conductive layer 166 and/or the second conductive layer 168 can be made of a material that has higher electrical conductivity than the upper electrode 118 or the lower electrode 114. For example, the first conductive layer 166 and/or the second conductive layer 168 can be made from gold or another conductive metal (e.g., copper or aluminum). In some embodiments, a material for the upper electrode 118 and/or the lower electrode 114 can have a relatively high acoustic impedance even if the electrical conductivity is not optimal. In some embodiments, the upper electrode 118 and/or the lower electrode 114 can include a material with higher acoustic impedance and/or lower electrical conductivity than the material of the first conductive layer 166 and/or the second conductive layer 168. The first conductive layer 166 and/or the second conductive layer 168 can have less effect on the acoustic vibrations, as compared to a BAW device that uses the relatively high acoustic impedance material of the electrode(s) 114, 118 to deliver electrical signals. The conductive layer 166 can be disposed above the gap, and the gap can insulate the conductive layer 166 from vibrations. Also, the first conductive layer 166 and/or the second conductive layer 168 can reduce ohmic loss, as compared to a BAW device that uses the lower conductivity material of the electrode(s) 114, 118 to deliver electrical signals. The BAW device 103 of FIG. 3, and other embodiments disclosed herein, can include the first conductive layer 166 and/or the second conductive layer 168, similar to the BAW device 105 of FIG. 4. The cavity 112 can be a recess formed in the substrate 110. The lower electrode 114 can extend along a plane from the connection with the second conductive layer 168. As shown in FIG. 4, in some embodiments, the cavity 112 can be formed above the substrate 110. The top surface of the substrate 110 can be planar. The lower electrode 114 and/or the piezoelectric layer 116 can include a step, with a lower region (e.g., which can be next to the cavity 112) and an upper region (e.g., which can be above the cavity 112). In some embodiments, the gap 122 can have a step, with a lower portion (e.g., which can be next to a portion of the piezoelectric layer 116) and an upper portion (e.g., which can be above the portion of the piezoelectric layer 116). In some embodiments, the gap can be disposed on a single plane. In some embodiments, the BAW device 105 can include an oxide layer 170 (e.g., silicon dioxide) between the substrate 110 and the lower electrode 114. The oxide layer 170 can partially or completely surround the cavity 112. The other BAW devices disclosed herein can include the oxide layer 170. In some embodiments, the oxide layer 170 can be omitted.

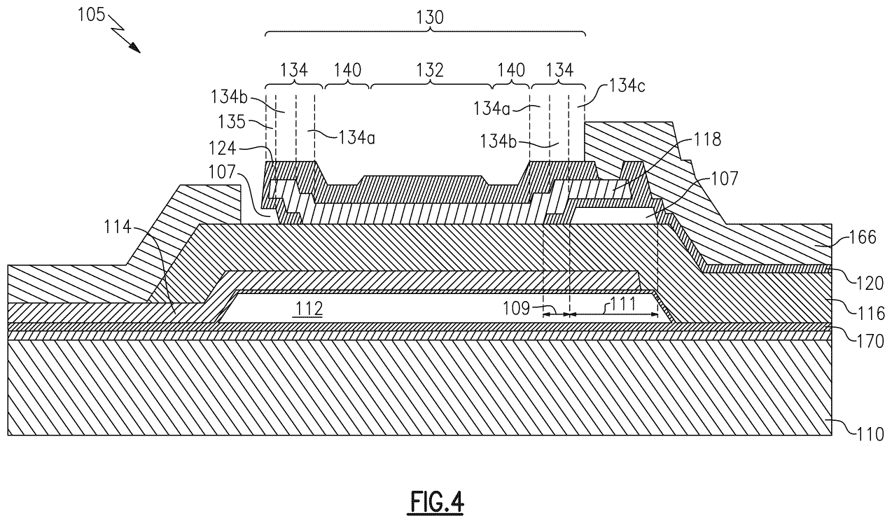

Although some of the BAW devices illustrated and described herein are FBAR devices, any suitable principles and advantages discussed herein can be applied to a solidly mounted resonator (SMR). FIG. 5 is a cross-sectional view of an example embodiment of a BAW device 300, which can be similar to any of the BAW devices of FIGS. 2, 3 and 4, except that the BAW device 300 of FIG. 5 is an SMR instead of an FBAR. As illustrated, the SMR 300 includes a piezoelectric layer 305, an upper electrode 310 on the piezoelectric layer 305, and a lower electrode 315 on a lower surface of the piezoelectric layer 305. The piezoelectric layer 305 can be an aluminum nitride (AlN) piezoelectric layer doped with one of various dopants. Bragg reflectors 320 are disposed as a solid acoustic mirror between the lower electrode 315 and a semiconductor substrate 325. The semiconductor substrate 325 can be a silicon substrate. Any suitable Bragg reflectors can be implemented. The illustrated acoustic Bragg reflectors include alternating low impedance layers and high impedance layers. As an example, the Bragg reflectors can include alternating silicon dioxide (SiO₂) layers as low impedance layers and tungsten (W) layers as high impedance layers 154, although other suitable materials could be used.

The BAW devices disclosed herein can be made using any suitable techniques or processes. In some cases, material or layers can be deposited by any suitable technique, and select portions of the deposited material can be removed, such as by etching, while other portions of the deposited material can be retained, such as by shielding the material from etching using a mask. Various other manufacturing processes could be used

An example manufacturing process is described, but other variations are possible. In some embodiments, a substrate (e.g., substrate 110) can be provided, such as a silicon (Si) wafer. A passivation layer (e.g., oxide layer 170) can be formed (e.g., deposited) onto or over the substrate. The passivation layer can be silicon dioxide. A cavity sacrificial layer can be formed (e.g., deposited and patterned) onto or over the substrate or passivation layer (e.g., to form the shape of the cavity 112). A membrane layer can be formed (e.g., deposited) onto or over the cavity sacrificial layer. The membrane layer can be the same material as the passivation layer (e.g., silicon dioxide). A conductive layer (e.g., metal) can be formed (e.g., deposited and patterned) onto or over the substrate, the cavity sacrificial material, or the membrane, such as to provide the lower electrode 114. A piezoelectric layer 116 can be formed (e.g., deposited) onto or over the conductive layer of the lower electrode 114. The piezoelectric layer 116 may be made from aluminum nitride (AlN). The AlN piezoelectric layer 116 may be doped with one or more of a group dopants, including scandium (Sc), yttrium (Y), hafnium (Hf), zirconium (Zr), tantalum (Ta), magnesium (Mg), niobium (Nb), silicon (Si), chromium (Cr), boron (B), titanium (Ti), gallium (Ga), calcium (Ca) and vanadium (V). The concentration of the dopant(s) may be varied in order to tune an electromechanical coupling factor of the resulting BAW device. A suspended frame sacrificial layer can be formed (e.g., deposited), such as onto or over the AlN piezoelectric layer 116. The suspended frame sacrificial layer can be patterned to provide the shape of the gap(s) 122. A first raised frame layer can be formed (e.g., deposited and patterned) to provide the first raised frame layer 120. A conductive layer (e.g., metal) can be formed (e.g., deposited) onto or over the first raised frame layer 120 or the suspended frame sacrificial material, such as to form the upper electrode 118. In some embodiments, a second raised frame layer 121 can be formed (e.g., deposited and patterned), such as onto or over the upper electrode 118. The conductive layer can be formed (e.g., patterned) to provide the shape of the upper electrode 118. The piezoelectric material can be formed (e.g., patterned) to form the shape of the AlN piezoelectric layer 116. A passivation layer 124 can be formed (e.g., deposited), such as onto or over the upper electrode 118 or second raised frame layer 121. In some embodiments, the passivation layer can be patterned to form the recessed frame region 140. In some embodiments, the passivation layer 124 can be formed (e.g., patterned) to provide an opening. A conductive (e.g., metal) layer can be formed (e.g., deposited and patterned) so that the conductive layer 166 extends into the opening in the passivation layer and contacts the upper electrode 118 or second raised frame layer 121. The conductive material can also form the second conductive layer 168 that has electrical contact with the lower electrode 114. In some embodiments, contacts (e.g., metal pads) can be formed, which can be configured to provide signals to and/or from the lower electrode 114 (e.g., through conductive layer 168) and the upper electrode (e.g., through conductive layer 166). The cavity sacrificial layer can be removed to form the cavity 112. The suspended frame sacrificial layer can be removed to form the gap(s) 122. In some embodiments, the cavity sacrificial layer and the suspended frame sacrificial layer can be removed together, such as during the same process step, or at the same time.

The BAW devices disclosed herein can be implemented as BAW resonators in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

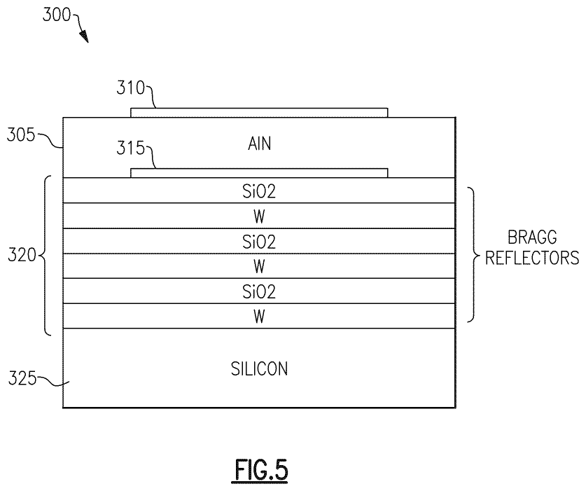

FIG. 6 is a cross-sectional view of an example of a wafer-level package (WLP) module 400 according to some embodiments. The WLP module 400 includes a first substrate 410 and a second substrate 411, the first substrate 410 and the second substrate 411 being both essentially planar with the main surfaces of the substrates being spaced apart and facing each other. The WLP module 400 includes at least one BAW device or resonator mounted on the first substrate 410 and at least one BAW device or resonator mounted on the second substrate 420. The first substrate 410 and the second substrate 411 may each be a support substrate similar to the support substrate 110 of the BAW devices of FIG. 2, 3, 4, or 5. The first substrate 410 and the second substrate 411 may be interconnected by through-level vias (TLVs) 402 and metallic interconnects 406. The TLVs 402 may reach through the depth of the first substrate 410 and may connect to a metallization layer 404 on the bottom or outer surface of the first substrate 410. The metallic interconnects 406 may be pillars arranged substantially perpendicular to the main surfaces of the substrates. The first substrate 410 may be covered or coated by a passivation layer 470. The second substrate 411 may be covered or coated by a passivation layer 471. The first substrate 410 and the second substrate 411 may be silicon substrates, and other suitable substrates can alternatively be implemented in place of the silicon substrate. The passivation layers 470 and 471 can be positioned between a lower electrode 114 of a BAW device mounted on the first substrate 410 or the second substrate 411, respectively, so that a cavity 112 is formed between the BAW device and the substrate onto which it is mounted.

The BAW devices mounted to the first substrate 410 and the second substrate 411 may be BAW resonators and may be configured similar to any of the BAW devices illustrated in and explained in conjunction with FIGS. 2, 3, 4, and 5. The BAW devices or resonators of FIG. 6 that are mounted on the first substrate 410 can include a first or lower electrode 114 positioned over the first substrate 410, an aluminum nitride based piezoelectric layer 416 positioned over the lower electrode 114, a second or upper electrode 118 positioned over the aluminum nitride based piezoelectric layer 416, a raised frame structure or layer positioned at least partially between the aluminum nitride based piezoelectric layer 416 and the upper electrode 118, and a passivation layer positioned over the upper electrode 118. The BAW devices or resonators mounted on the first substrate 410 can include an active region 130 that has a main acoustically active region and a raised frame region at least partially, or fully, surrounding the main acoustically active region (e.g., in plan view). Similarly, the BAW devices or resonators of FIG. 6 that are mounted on the second substrate 411 can include a first or lower electrode 114 positioned over the second substrate 411, an aluminum nitride based piezoelectric layer 426 positioned over the lower electrode 114, a second or upper electrode 118 positioned over the aluminum nitride based piezoelectric layer 426, a raised frame structure or layer positioned at least partially between the aluminum nitride based piezoelectric layer 426 and the upper electrode 118, and a passivation layer positioned over the upper electrode 118. The BAW device or resonator mounted on the second substrate 411 can include an active region 130 that has a main acoustically active region and a raised frame region at least partially, or fully, surrounding the main acoustically active region (e.g., in plan view).

In the BAW devices or resonators mounted on the first substrate 410 a first conductive layer 166 can be disposed over at least a portion of the passivation layer. The passivation layer can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap, although other locations could also be used. The conductive layer 166 can contact the upper electrode 118, can extend through the opening in the passivation layer, and/or can extend outward from the opening. Electrical signals and/or electrical power can be delivered to and/or from the upper electrode 118 through the first conductive layer 166. The opening or electrical contact between the first conductive layer 166 and the upper electrode 118 can be disposed directly above the lower electrode 114, the piezoelectric layer 416, the upper electrode 118, a portion of the gap, and/or a portion of the raised frame layer. In some embodiments, the active region 130 can omit the area covered by the first conductive layer 166, as shown in FIG. 6, even if that area includes overlapping of the piezoelectric layer 416, the lower electrode 114, and the upper electrode 118. In the BAW devices or resonators mounted on the first substrate 410 a second conductive layer 168 can be disposed over a portion of the lower electrode 114. For example, a portion of the lower electrode 114 can extend outward past an end of the piezoelectric layer 416. The second conductive layer 168 can be positioned over (e.g., in direct contact with) that portion of the lower electrode 114. The second conductive layer 168 can provide electrical signals and/or electrical power to and/or from the lower electrode 114. In some embodiments, either or both of the first conductive layer 166 and the second conductive layer 168 can be omitted. For example, electrical signals can be delivered directly to or from either or both of the electrodes 114, 118, in some implementations. A first conductive layer of low resistivity material 466 such as copper or aluminum may be placed over the first conductive layer 166. A second conductive layer of low resistivity material 468 such as copper or aluminum may be placed over the second conductive layer 168. In the BAW devices or resonators mounted on the second substrate 411 a first conductive layer 166 can be disposed over at least a portion of the passivation layer. The passivation layer can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap, although other locations could also be used. The conductive layer 166 can contact the upper electrode 118, can extend through the opening in the passivation layer, and/or can extend outward from the opening. Electrical signals and/or electrical power can be delivered to and/or from the upper electrode 118 through the first conductive layer 166. The opening or electrical contact between the first conductive layer 166 and the upper electrode 118 can be disposed directly above the lower electrode 114, the piezoelectric layer 426, the upper electrode 118, a portion of the gap, and/or a portion of the raised frame layer. In some embodiments, the active region 130 can omit the area covered by the first conductive layer 166, as shown in FIG. 6, even if that area includes overlapping of the piezoelectric layer 426, the lower electrode 114, and the upper electrode 118. In the BAW devices or resonators mounted on the second substrate 411 a second conductive layer 168 can be disposed over a portion of the lower electrode 114. For example, a portion of the lower electrode 114 can extend outward past an end of the piezoelectric layer 426. The second conductive layer 168 can be positioned over (e.g., in direct contact with) that portion of the lower electrode 114. The second conductive layer 168 can provide electrical signals and/or electrical power to and/or from the lower electrode 114. In some embodiments, either or both of the first conductive layer 166 and the second conductive layer 168 can be omitted. For example, electrical signals can be delivered directly to or from either or both of the electrodes 114, 118, in some implementations. A passivation or isolation layer 466 may be placed over the first conductive layer 166. A passivation or isolation layer 468 may be placed over the second conductive layer 168.

In order to adjust the electromechanical coupling coefficients (kₜ²) of the BAW devices or resonators, the respective aluminum nitride (AlN) based piezoelectric layer may be doped with different dopants. For example, the AlN base piezoelectric layer 416 of the BAW devices or resonators mounted on the first substrate 410 may be doped with elements selected from the group of scandium (Sc), yttrium (Y), hafnium (Hf), zirconium (Zr), tantalum (Ta), magnesium (Mg), niobium (Nb), silicon (Si), and chromium (Cr). Doping the AlN piezoelectric layers 416 with one or more of the group of Sc, Y, Hf, Zr, Ta, Mg, Nb, Si, and Cr yield increased kₜ² values. Similarly, the AlN base piezoelectric layer 426 of the BAW devices or resonators mounted on the second substrate 411 may be doped with elements selected from the group of boron (B), titanium (Ti), gallium (Ga), calcium (Ca) and vanadium (V). Doping the Al piezoelectric layers 426 with one or more of the group of B, Ti, Ga, Ca, and V yield decreased kₜ² values. It may be possible to use different dopants for the AlN base piezoelectric layer 426 than for the AlN base piezoelectric layer 416. In other implementations, it may be possible to use dopants for the AlN base piezoelectric layer 416 of the BAW devices or resonators mounted on the first substrate 410, while the AlN base piezoelectric layer 426 of the BAW devices or resonators mounted on the second substrate 411 is pure AlN. Alternatively, it may be possible to use dopants for the AlN base piezoelectric layer 426 of the BAW devices or resonators mounted on the second substrate 420, while the AlN base piezoelectric layer 416 of the BAW devices or resonators mounted on the first substrate 416 is pure AlN. Generally, the BAW devices or resonators mounted on the same substrate have AlN base piezoelectric layer 426 with the same dopants or with pure AlN each in order to adjust the electromechanical coupling coefficient (kₜ²) of the BAW devices or resonators mounted on the same substrate to the same value.

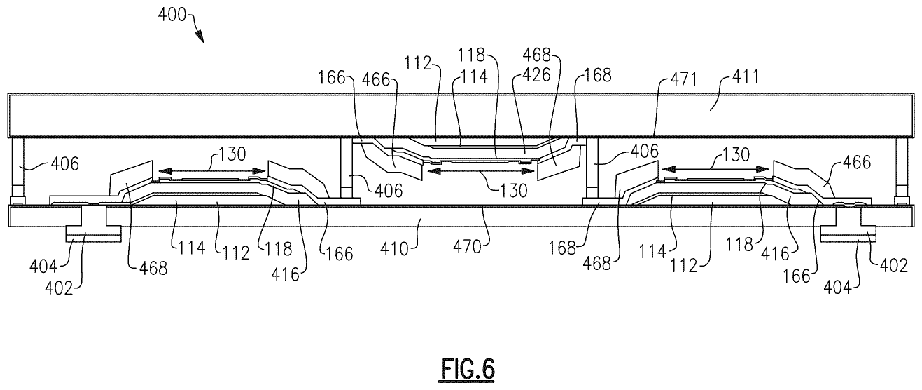

FIG. 7 is a cross-sectional view of another example of a wafer-level package (WLP) module 500 according to some further embodiments. The WLP module 500 includes a first substrate 510 and a second substrate 511, the first substrate 510 and the second substrate 511 being both essentially planar with the main surfaces of the substrates being spaced apart and facing each other. The WLP module 500 includes at least one BAW device or resonator mounted on the first substrate 510 and at least one BAW device or resonator mounted on the second substrate 520. The first substrate 510 and the second substrate 511 may each be a support substrate similar to the support substrate 110 of the BAW devices of FIG. 2, 3, 4, or 5. The first substrate 510 and the second substrate 511 may be interconnected by metallic interconnects 506. The metallic interconnects 506 may be pillars arranged substantially perpendicular to the main surfaces of the substrates. The first substrate 510 may be covered or coated by a passivation layer 570. The second substrate 511 may be covered or coated by a passivation layer 571. The first substrate 510 and the second substrate 511 may be silicon substrates, and other suitable substrates can alternatively be implemented in place of the silicon substrate. The passivation layers 570 and 571 can be positioned between a lower electrode 114 of a BAW device mounted on the first substrate 510 or the second substrate 511, respectively, so that a cavity 112 is formed between the BAW device and the substrate onto which it is mounted. In contrast to the cavities 112 of FIG. 6, the cavities 112 in FIG. 7 may be recessed into the first substrate 510 or second substrate 511.

The BAW devices mounted to the first substrate 510 and the second substrate 511 may be BAW resonators and may be configured similar to any of the BAW devices illustrated in and explained in conjunction with FIGS. 2, 3, 4, and 5. The BAW devices or resonators of FIG. 7 that are mounted on the first substrate 510 can include a first or lower electrode 114 positioned over the first substrate 510, an aluminum nitride based piezoelectric layer 516 positioned over the lower electrode 114, a second or upper electrode 118 positioned over the aluminum nitride based piezoelectric layer 516, a raised frame structure or layer positioned at least partially between the aluminum nitride based piezoelectric layer 516 and the upper electrode 118, and a passivation layer positioned over the upper electrode 118. The BAW devices or resonators mounted on the first substrate 510 can include an active region 130 that has a main acoustically active region and a raised frame region at least partially, or fully, surrounding the main acoustically active region (e.g., in plan view). Similarly, the BAW devices or resonators of FIG. 7 that are mounted on the second substrate 411 can include a first or lower electrode 114 positioned over the second substrate 511, an aluminum nitride based piezoelectric layer 526 positioned over the lower electrode 114, a second or upper electrode 118 positioned over the aluminum nitride based piezoelectric layer 526, a raised frame structure or layer positioned at least partially between the aluminum nitride based piezoelectric layer 526 and the upper electrode 118, and a passivation layer positioned over the upper electrode 118. The BAW device or resonator mounted on the second substrate 511 can include an active region 130 that has a main acoustically active region and a raised frame region at least partially, or fully, surrounding the main acoustically active region (e.g., in plan view).

In the BAW devices or resonators mounted on the first substrate 510 a first conductive layer 166 can be disposed over at least a portion of the passivation layer. The passivation layer can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap, although other locations could also be used. The conductive layer 166 can contact the upper electrode 118, can extend through the opening in the passivation layer, and/or can extend outward from the opening. Electrical signals and/or electrical power can be delivered to and/or from the upper electrode 118 through the first conductive layer 166. The opening or electrical contact between the first conductive layer 166 and the upper electrode 118 can be disposed directly above the lower electrode 114, the piezoelectric layer 516, the upper electrode 118, a portion of the gap, and/or a portion of the raised frame layer. In some embodiments, the active region 130 can omit the area covered by the first conductive layer 166, as shown in FIG. 7, even if that area includes overlapping of the piezoelectric layer 516, the lower electrode 114, and the upper electrode 118. In the BAW devices or resonators mounted on the first substrate 510 a second conductive layer 168 can be disposed over a portion of the lower electrode 114. For example, a portion of the lower electrode 114 can extend outward past an end of the piezoelectric layer 516. The second conductive layer 168 can be positioned over (e.g., in direct contact with) that portion of the lower electrode 114. The second conductive layer 168 can provide electrical signals and/or electrical power to and/or from the lower electrode 114. In some embodiments, either or both of the first conductive layer 166 and the second conductive layer 168 can be omitted. For example, electrical signals can be delivered directly to or from either or both of the electrodes 114, 118, in some implementations. A first conductive layer of low resistivity material 566 such as copper or aluminum may be placed over the first conductive layer 166. A second conductive layer of low resistivity material 568 such as copper or aluminum may be placed over the second conductive layer 168. In the BAW devices or resonators mounted on the second substrate 411 a first conductive layer 166 can be disposed over at least a portion of the passivation layer. The passivation layer can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap, although other locations could also be used. The conductive layer 166 can contact the upper electrode 118, can extend through the opening in the passivation layer, and/or can extend outward from the opening. Electrical signals and/or electrical power can be delivered to and/or from the upper electrode 118 through the first conductive layer 166. The opening or electrical contact between the first conductive layer 166 and the upper electrode 118 can be disposed directly above the lower electrode 114, the piezoelectric layer 426, the upper electrode 118, a portion of the gap, and/or a portion of the raised frame layer. In some embodiments, the active region 130 can omit the area covered by the first conductive layer 166, as shown in FIG. 7, even if that area includes overlapping of the piezoelectric layer 526, the lower electrode 114, and the upper electrode 118. In the BAW devices or resonators mounted on the second substrate 511 a second conductive layer 168 can be disposed over a portion of the lower electrode 114. For example, a portion of the lower electrode 114 can extend outward past an end of the piezoelectric layer 526. The second conductive layer 168 can be positioned over (e.g., in direct contact with) that portion of the lower electrode 114. The second conductive layer 168 can provide electrical signals and/or electrical power to and/or from the lower electrode 114. In some embodiments, either or both of the first conductive layer 166 and the second conductive layer 168 can be omitted. For example, electrical signals can be delivered directly to or from either or both of the electrodes 114, 118, in some implementations. A first conductive layer of low resistivity material 566 such as copper or aluminum may be placed over the first conductive layer 166. A second conductive layer of low resistivity material 568 such as copper or aluminum may be placed over the second conductive layer 168.

In order to adjust the electromechanical coupling coefficients (kₜ²) of the BAW devices or resonators, the respective aluminum nitride (AlN) based piezoelectric layer may be doped with different dopants. For example, the AlN base piezoelectric layer 516 of the BAW devices or resonators mounted on the first substrate 510 may be doped with elements selected from the group of scandium (Sc), yttrium (Y), hafnium (Hf), zirconium (Zr), tantalum (Ta), magnesium (Mg), niobium (Nb), silicon (Si), and chromium (Cr). Doping the AlN piezoelectric layers 516 with one or more of the group of Sc, Y, Hf, Zr, Ta, Mg, Nb, Si, and Cr yield increased kₜ² values. Similarly, the AlN base piezoelectric layer 526 of the BAW devices or resonators mounted on the second substrate 511 may be doped with elements selected from the group of boron (B), titanium (Ti), gallium (Ga), calcium (Ca) and vanadium (V). Doping the AlN piezoelectric layers 526 with one or more of the group of B, Ti, Ga, Ca, and V yield decreased kₜ² values. It may be possible to use different dopants for the AlN base piezoelectric layer 526 than for the AlN base piezoelectric layer 516. In other implementations, it may be possible to use dopants for the AlN base piezoelectric layer 516 of the BAW devices or resonators mounted on the first substrate 510, while the AlN base piezoelectric layer 526 of the BAW devices or resonators mounted on the second substrate 511 is pure AlN. Alternatively, it may be possible to use dopants for the AlN base piezoelectric layer 526 of the BAW devices or resonators mounted on the second substrate 520, while the AlN base piezoelectric layer 516 of the BAW devices or resonators mounted on the first substrate 516 is pure AlN. Generally, the BAW devices or resonators mounted on the same substrate have AlN base piezoelectric layer 526 with the same dopants or with pure AlN each in order to adjust the electromechanical coupling coefficient (kₜ²) of the BAW devices or resonators mounted on the same substrate to the same value.

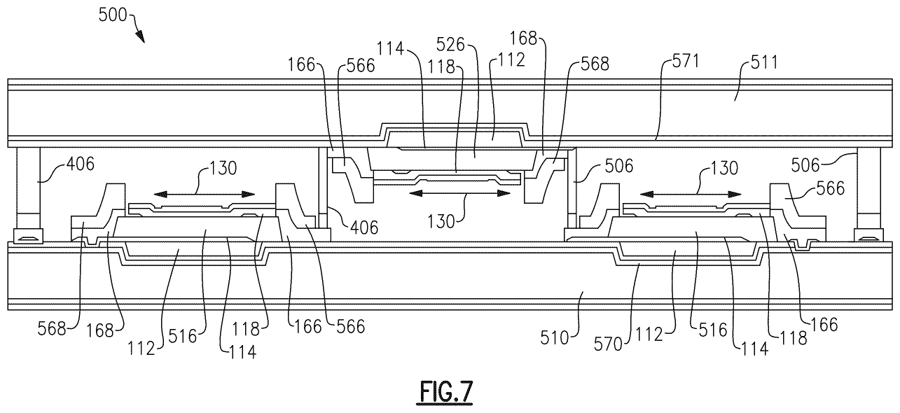

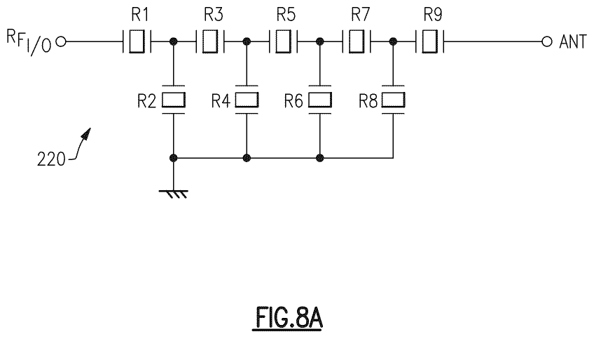

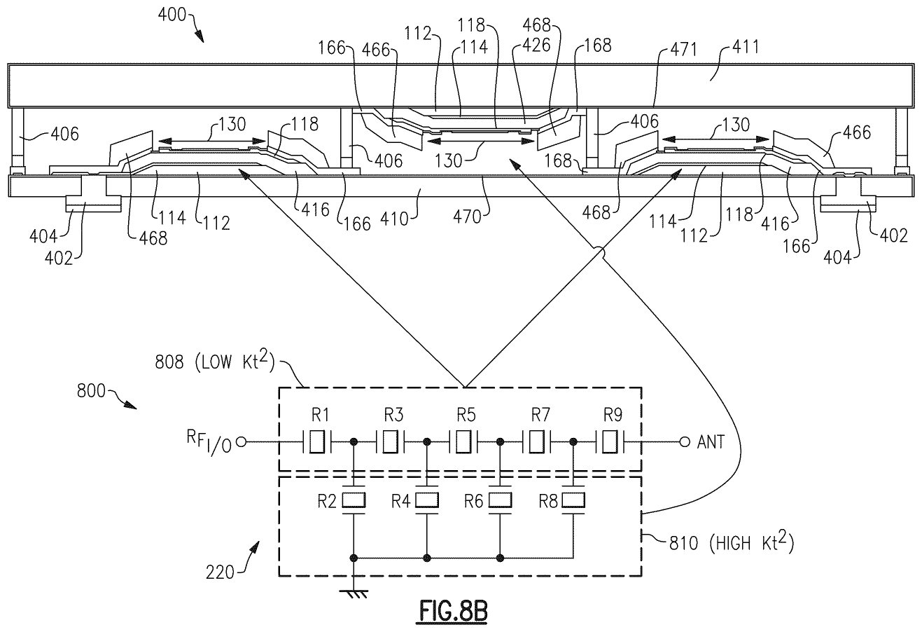

FIG. 8A is a schematic diagram of an example of an acoustic wave ladder filter 220. The acoustic wave ladder filter 220 can be a transmit filter or a receive filter. The acoustic wave ladder filter 220 can be a band pass filter arranged to filter a radio frequency signal. The acoustic wave filter 220 can include series resonators R1, R3, R5, R7, and R9 and shunt resonators R2, R4, R6, and R8 coupled between a radio frequency input/output port RFI/O and an antenna port ANT. The radio frequency input/output port RFI/O can be a transmit port in a transmit filter or a receive port in a receive filter. One or more of the illustrated acoustic wave resonators can be a bulk acoustic wave resonator in accordance with any suitable principles and advantages discussed herein. An acoustic wave ladder filter can include any suitable number of series resonators and any suitable number of shunt resonators. In particular, the acoustic wave ladder filter 220 of FIG. 8 may include one or more WLP modules 400 or 500 as illustrated in FIG. 6 or 7. The WLP modules 400 or 500 of the acoustic wave ladder filter 220 may employ series resonators that are implemented by BAW resonators mounted on the first substrate of the WLP modules 400 or 500, while the shunt resonators of the acoustic wave ladder filter 220 are implemented by BAW resonators mounted on the second substrate of the WLP modules 400 or 500.

FIG. 8B shows an example of an acoustic wave ladder filter 800 where the first group 808 of series BAW resonators have a lower kₜ² value than the second group 810 of shunt resonators. For example, the first group 808 can be implemented by BAW resonators mounted on the first substrate 410 of the WLP module 400 of FIG. 6, while the second group 810 may be implemented by the BAW resonators mounted on the second substrate 411 of the WLP module 400 of FIG. 6. In one embodiment, the first group 808 has AlN piezoelectric layers 416 doped with one or more of the group of B, Ti, Ga, Ca, and V, yielding decreased kₜ² values, and the second group 810 has AlN piezoelectric layers 426 doped with one or more of the group of Sc, Y, Hf, Zr, Ta, Mg, Nb, Si, and Cr, yielding increased kₜ² values. In another embodiment, the first group 808 has AlN piezoelectric layers 416 doped with one or more of the group of B, Ti, Ga, Ca, and V and the second group 810 has AlN piezoelectric layers 426 comprising pure AlN. In another embodiment, the first group 808 has AlN piezoelectric layers 416 comprising pure AlN and the second group 810 has AlN piezoelectric layers 426 doped with one or more of the group of Sc, Y, Hf, Zr, Ta, Mg, Nb, Si, and Cr.

FIG. 8C shows an example of an acoustic wave ladder filter 802 where the first group 812 of series BAW resonators have a higher kₜ² value than the second group 814 of shunt resonators. For example, the first group 812 can be implemented by BAW resonators mounted on the first substrate 410 of the WLP module 400 of FIG. 6, while the second group 814 may be implemented by the BAW resonators mounted on the second substrate 411 of the WLP module 400 of FIG. 6. In one embodiment, the first group 812 has AlN piezoelectric layers 416 doped with one or more of the group of Sc, Y, Hf, Zr, Ta, Mg, Nb, Si, and Cr, yielding increased kₜ² values, and the second group 814 has piezoelectric layers 426 doped with one or more of the group of B, Ti, Ga, Ca, and V, yielding decreased kₜ² values. In another embodiment, the first group 812 has AlN piezoelectric layers 416 doped with one or more of the group of Sc, Y, Hf, Zr, Ta, Mg, Nb, Si, and Cr and the second group 814 has AlN piezoelectric layers 426 comprising pure AlN. In another embodiment, the first group 812 has AlN piezoelectric layers 416 comprising pure AlN and the second group 814 has AlN piezoelectric layers 426 doped with one or more of the group of B, Ti, Ga, Ca, and V.

FIG. 8D shows an example of an acoustic wave ladder filter 804 where the first group 816 of BAW resonators (series resonators R1, R3 and shunt resonators R2, R4) have a higher kₜ² value than the second group 818 resonators (series resonators R5, R7, R9 and shunt resonators R6, R8). For example, the first group 816 can be implemented by BAW resonators mounted on the first substrate 410 of the WLP module 400 of FIG. 6, while the second group 818 may be implemented by the BAW resonators mounted on the second substrate 411 of the WLP module 400 of FIG. 6. In one embodiment, the first group 816 has AlN piezoelectric layers 416 doped with one or more of the group of Sc, Y, Hf, Zr, Ta, Mg, Nb, Si, and Cr, yielding increased kₜ² values, and the second group 818 has AlN piezoelectric layers 426 doped with one or more of the group of B, Ti, Ga, Ca, and V, yielding decreased kₜ² values. In another embodiment, the first group 816 has AlN piezoelectric layers 416 doped with one or more of the group of Sc, Y, Hf, Zr, Ta, Mg, Nb, Si, and Cr and the second group 818 has AlN piezoelectric layers 426 comprising pure AlN. In another embodiment, the first group 816 has AlN piezoelectric layers 416 comprising pure AlN and the second group 818 has AlN piezoelectric layers 426 doped with one or more of the group of B, Ti, Ga, Ca, and V.

FIG. 8E shows an example of an acoustic wave ladder filter 806 where the first group 820 of BAW resonators (series resonators R1, R3 and shunt resonators R2, R4) have a lower kₜ² value than the second group 822 of resonators (series resonators R5, R7, R9 and shunt resonators R6, R8). For example, the first group 820 can be implemented by BAW resonators mounted on the first substrate 410 of the WLP module 400 of FIG. 6, while the second group 822 may be implemented by the BAW resonators mounted on the second substrate 411 of the WLP module 400 of FIG. 6. In one embodiment, the first group 820 may have AlN piezoelectric layers 416 doped with one or more of the group of B, Ti, Ga, Ca, and V, yielding decreased kₜ² values, and the second group 822 may have AlN piezoelectric layers 426 doped with one or more of the group of Sc, Y, Hf, Zr, Ta, Mg, Nb, Si, and Cr, yielding increased kₜ² values. In another embodiment, the first group 820 may have AlN piezoelectric layers 416 doped with one or more of the group of B, Ti, Ga, Ca, and V and the second group 822 may have AlN piezoelectric layers 426 comprising pure AlN. In another embodiment, the first group 820 has AlN piezoelectric layers 416 comprising pure AlN and the second group 822 has AlN piezoelectric layers 426 doped with one or more of the group of Sc, Y, Hf, Zr, Ta, Mg, Nb, Si, and Cr.

While the acoustic wave ladder filters of FIGS. 8B-8E have been described with respect to the WLP module 400 of FIG. 6, the ladder filters of FIGS. 8B-8E are compatible with other WLP modules, such as the WLP module 500 of FIG. 7, for example.

An acoustic wave filter can be arranged in any other suitable filter topology, such as a lattice topology or a hybrid ladder and lattice topology. A bulk acoustic wave resonator in accordance with any suitable principles and advantages disclosed herein can be implemented in a band pass filter. In some other applications, a bulk acoustic wave resonator in accordance with any suitable principles and advantages disclosed herein can be implemented in a band stop filter.

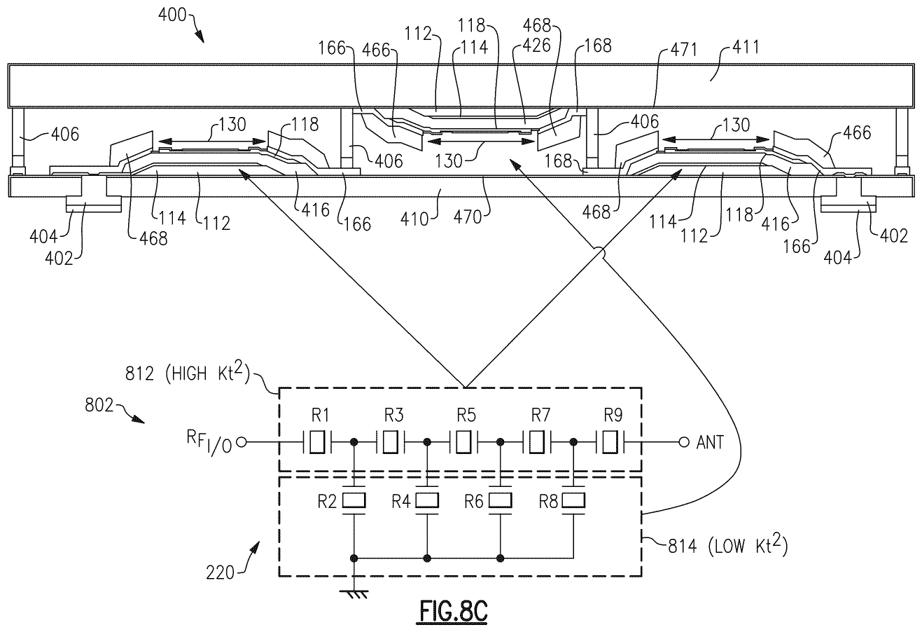

FIG. 9 is a schematic diagram of an example of a duplexer 230. The duplexer 230 can include a transmit filter 231 and a receive filter 232 coupled to each other at an antenna node ANT. A shunt inductor L1 can be connected to the antenna node ANT. The transmit filter 231 and the receive filter 232 can both be acoustic wave ladder filters in the duplexer 230.

The transmit filter 231 can filter a radio frequency signal and provide a filtered radio frequency signal to the antenna node ANT. A series inductor L2 can be coupled between a transmit input node TX and the acoustic wave resonators of the transmit filter 231. The illustrated transmit filter 231 can include acoustic wave resonators T01 to T09. One or more of these resonators can be bulk acoustic wave resonators in accordance with any suitable principles and advantages disclosed herein. The illustrated receive filter 232 can include acoustic wave resonators R01 to R09. One or more of these resonators can be bulk acoustic wave resonators in accordance with any suitable principles and advantages disclosed herein. The receive filter 232 can filter a radio frequency signal received at the antenna node ANT. A series inductor L3 can be coupled between the resonator and a receive output node RX. The receive output node RX of the receive filter 232 provides a radio frequency receive signal.

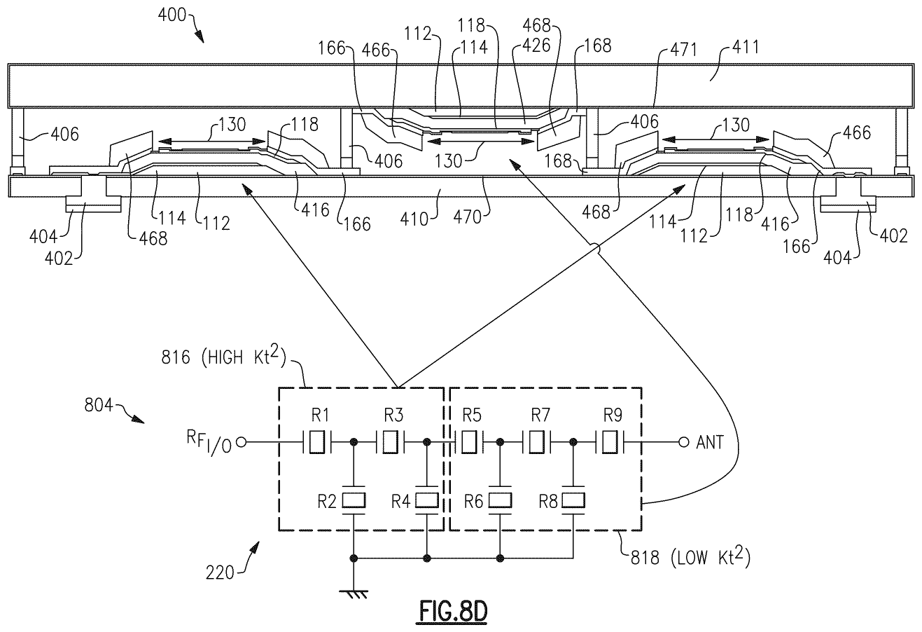

FIG. 10 is a schematic diagram of a multiplexer 235 that includes an acoustic wave filter according to an embodiment. The multiplexer 235 can include a plurality of filters 236A to 236N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 236A, 236B, and 236N can be coupled between the common node COM and a respective input/output node RFI/O1, RFI/O2, and RFI/ON.

In some instances, all filters of the multiplexer 235 can be receive filters. According to some other instances, all filters of the multiplexer 235 can be transmit filters. In various applications, the multiplexer 235 can include one or more transmit filters and one or more receive filters. Accordingly, the multiplexer 235 can include any suitable number of transmit filters and any suitable number of receive filters. Each of the illustrated filters can be band pass filters having different respective pass bands.

The multiplexer 235 is illustrated with hard multiplexing with the filters 236A to 236N having fixed connections to the common node COM. In some other applications, one or more of the filters of a multiplexer can be electrically connected to the common node by a respective switch. Any of such filters can include a bulk acoustic wave resonator according to any suitable principles and advantages disclosed herein.

A first filter 236A can be an acoustic wave filter having a first pass band and arranged to filter a radio frequency signal. The first filter 236A can include one or more bulk acoustic wave resonators according to any suitable principles and advantages disclosed herein. A second filter 236B has a second pass band. In some embodiments, a raised frame structure of one or more bulk acoustic wave resonators of the first filter 236A can move a raised frame mode of the one or more bulk acoustic wave resonators away from the second passband. This can increase a reflection coefficient (Gamma) of the first filter 236A in the pass band of the second filter 236B. The raised frame structure of the bulk acoustic wave resonator of the first filter 236A can also move the raised frame mode away from the passband of one or more other filters of the multiplexer 235.

In certain instances, the common node COM of the multiplexer 235 can be arranged to receive a carrier aggregation signal including at least a first carrier associated with the first passband of the first filter 236A and a second carrier associated with the second passband of the second filter 236B. A multi-layer raised frame structure of a bulk acoustic wave resonator of the first filter 236A can maintain and/or increase a reflection coefficient of the first filter 236A in the second passband of the second filter 236B that is associated with the second carrier of the carrier aggregation signal.

The filters 236B to 236N of the multiplexer 235 can include one or more acoustic wave filters, one or more acoustic wave filters that include at least one bulk acoustic wave resonator with a raised frame structure, one or more LC filters, one or more hybrid acoustic wave LC filters, or any suitable combination thereof.

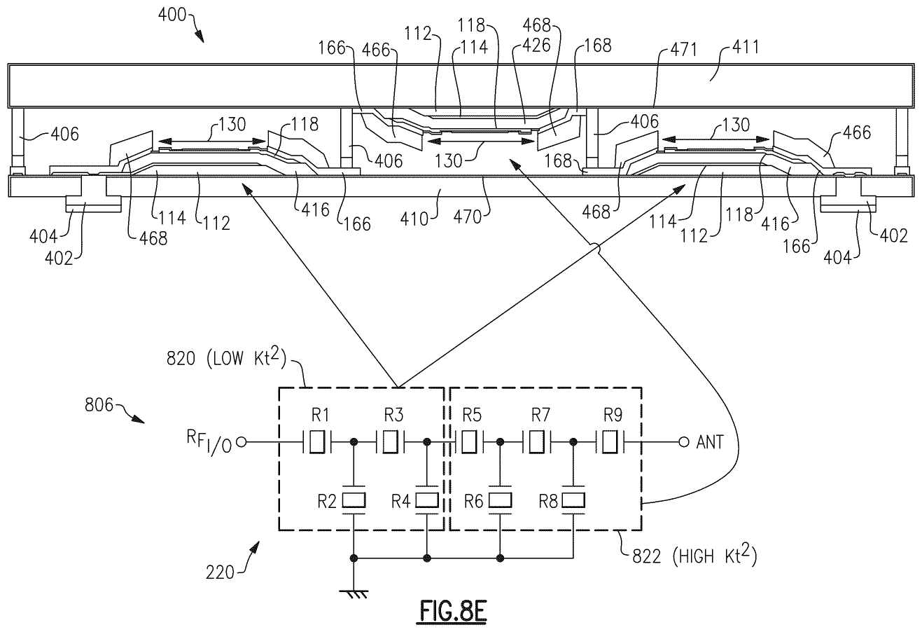

The WLP modules with bulk acoustic wave resonators disclosed herein can be implemented in a variety of packaged modules. Some example packaged modules will now be discussed in which any suitable principles and advantages of the bulk acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 11, 12A, 12B, and 13 are schematic block diagrams of illustrative packaged modules according to certain embodiments. Certain example packaged modules can include one or more radio frequency amplifiers, such as one or more power amplifiers and/or one or more low noise amplifiers. Any suitable combination of features of these modules can be implemented with each other. While duplexers are illustrated in the example packaged modules of FIGS. 11, 12A, 12B, and 13, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 11 is a schematic block diagram of an example module 240 that includes duplexers 241A to 241N and an antenna switch 242. One or more filters of the duplexers 241A to 241N can include any suitable number of multi-layer raised frame bulk acoustic wave resonators in accordance with any suitable principles and advantages discussed herein. Any suitable number of duplexers 241A to 241N can be implemented. The antenna switch 242 can have a number of throws corresponding to the number of duplexers 241A to 241N. The antenna switch 242 can electrically couple a selected duplexer to an antenna port of the module 240.

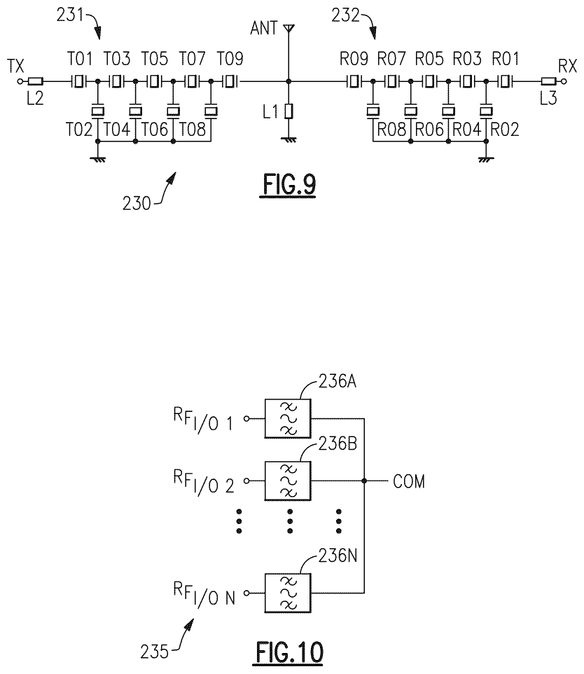

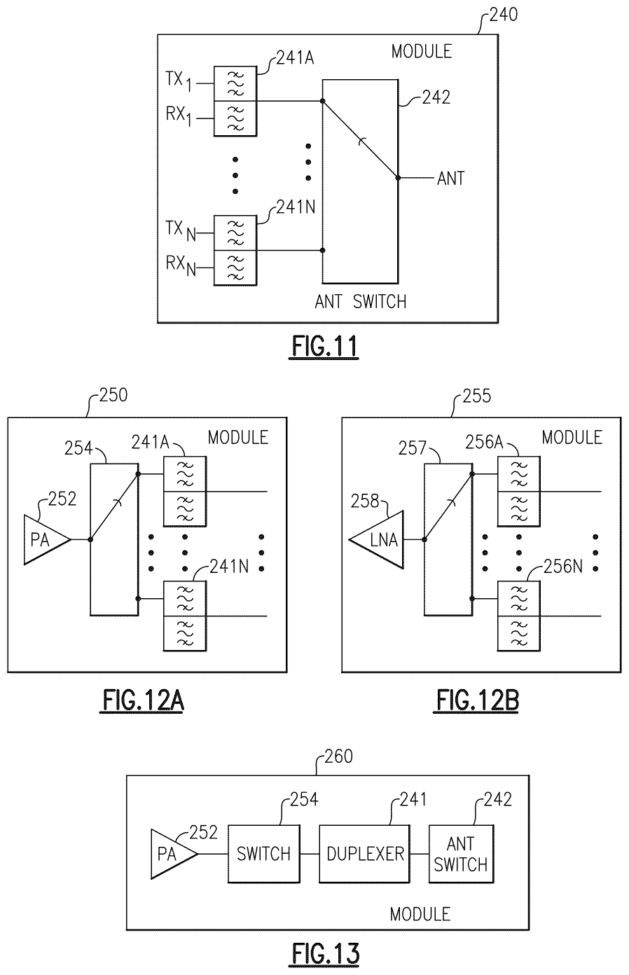

FIG. 12A is a schematic block diagram of an example module 250 that includes a power amplifier 252, a radio frequency switch 254, and duplexers 241A to 241N in accordance with one or more embodiments. The power amplifier 252 can amplify a radio frequency signal. The radio frequency switch 254 can be a multi-throw radio frequency switch. The radio frequency switch 254 can electrically couple an output of the power amplifier 252 to a selected transmit filter of the duplexers 241A to 241N. One or more filters of the duplexers 241A to 241N can include any suitable number of raised frame bulk acoustic wave resonators in accordance with any suitable principles and advantages discussed herein. Any suitable number of duplexers 241A to 241N can be implemented.

FIG. 12B is a schematic block diagram of an example module 255 that includes filters 256A to 256N, a radio frequency switch 257, and a low noise amplifier 258 according to one or more embodiments. One or more filters of the filters 256A to 256N can include any suitable number of raised frame bulk acoustic wave resonators in accordance with any suitable principles and advantages disclosed herein. Any suitable number of filters 256A to 256N can be implemented. The illustrated filters 256A to 256N can be receive filters. In some embodiments (not illustrated), one or more of the filters 256A to 256N can be included in a multiplexer that also includes a transmit filter. The radio frequency switch 257 can be a multi-throw radio frequency switch. The radio frequency switch 257 can electrically couple an output of a selected filter of filters 256A to 256N to the low noise amplifier 257. In some embodiments (not illustrated), a plurality of low noise amplifiers can be implemented. The module 255 can include diversity receive features in certain applications.

FIG. 13 is a schematic block diagram of an example module 260 that includes a power amplifier 252, a radio frequency switch 254, and a duplexer 241 that includes a raised frame bulk acoustic wave device in accordance with one or more embodiments, and an antenna switch 242. The module 260 can include elements of the module 240 and elements of the module 250.

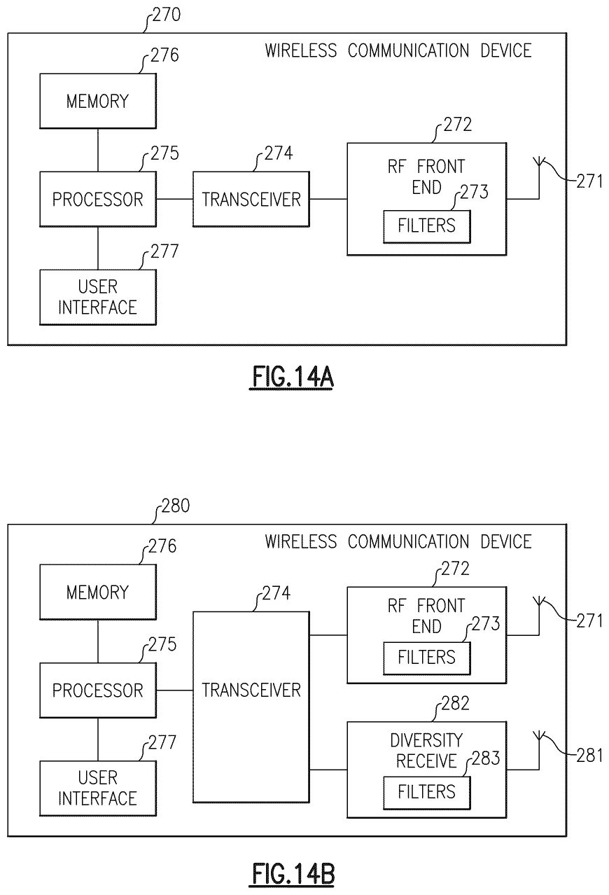

One or more filters with any suitable number of raised frame bulk acoustic devices can be implemented in a variety of wireless communication devices. FIG. 14A is a schematic block diagram of an example wireless communication device 270 that includes a filter 273 with one or more raised frame bulk acoustic wave resonators in accordance with any suitable principles and advantages disclosed herein. The wireless communication device 270 can be any suitable wireless communication device. For instance, a wireless communication device 270 can be a mobile phone, such as a smart phone. As illustrated, the wireless communication device 270 includes an antenna 271, a radio frequency (RF) front end 272 that includes filter 273, an RF transceiver 274, a processor 275, a memory 276, and a user interface 277. The antenna 271 can transmit RF signals provided by the RF front end 272. The antenna 271 can provide received RF signals to the RF front end 272 for processing.

The RF front end 272 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 272 can transmit and receive RF signals associated with any suitable communication standards. Any of the multi-layer raised frame bulk acoustic wave resonators disclosed herein can be implemented in filters 273 of the RF front end 272.

The RF transceiver 274 can provide RF signals to the RF front end 272 for amplification and/or other processing. The RF transceiver 274 can also process an RF signal provided by a low noise amplifier of the RF front end 272. The RF transceiver 274 is in communication with the processor 275. The processor 275 can be a baseband processor. The processor 275 can provide any suitable base band processing functions for the wireless communication device 270. The memory 276 can be accessed by the processor 275. The memory 276 can store any suitable data for the wireless communication device 270. The processor 275 is also in communication with the user interface 277. The user interface 277 can be any suitable user interface, such as a display.

FIG. 14B is a schematic diagram of a wireless communication device 280 that includes filters 273 in a radio frequency front end 272 and second filters 283 in a diversity receive module 282. The wireless communication device 280 is like the wireless communication device 270 of FIG. 14A, except that the wireless communication device 280 also includes diversity receive features. As illustrated in FIG. 14B, the wireless communication device 280 can include a diversity antenna 281, a diversity module 282 configured to process signals received by the diversity antenna 281 and including second filters 283, and a transceiver 274 in communication with both the radio frequency front end 272 and the diversity receive module 282. One or more of the second filters 283 can include a bulk acoustic wave resonator with a multi-layer raised frame structure in accordance with any suitable principles and advantages disclosed herein.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 Megahertz (MHz) to 7.125 Gigahertz (GHz), for example, as specified in a current 5G NR specification. A filter arranged to filter a radio frequency signal in a 5G NR FR1 operating band can include one or more bulk acoustic wave resonators be implemented in accordance with any suitable principles and advantages disclosed herein.

5G NR carrier aggregation specifications can present technical challenges. For example, 5G carrier aggregations can have wider bandwidth and/or channel spacing than fourth generation (4G) Long Term Evolution (LTE) carrier aggregations. Carrier aggregation bandwidth in certain 5G FR1 applications can be in a range from 120 MHz to 400 MHZ, such as in a range from 120 MHz to 200 MHz. Carrier spacing in certain 5G FR1 applications can be up to 100 MHz. Bulk acoustic wave resonators with a raised frame structure as disclosed herein can achieve low insertion loss and low Gamma loss, in some embodiments. The frequency of a raised frame mode of such a bulk acoustic wave resonator can be moved significantly away from a resonant frequency of the bulk acoustic wave resonator. Accordingly, the raised frame mode can be outside of a carrier aggregation band even with the wider carrier aggregation bandwidth and/or channel spacing within FR1 in 5G specifications. This can reduce and/or eliminate Gamma degradation in an operating band of another carrier of a carrier aggregation. In some instances, Gamma can be increased in the operating band of the other carrier of the carrier aggregation.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHZ, such as in a frequency range from about 450 MHz to 8.5 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, devices, modules, apparatus, methods, and systems described herein may be embodied in a variety of other forms. Furthermore, various omissions, substitutions and changes in the form of the resonators, devices, modules, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A wafer-level packaged module, comprising:
a first substrate having a first bulk acoustic wave device mounted thereon, the first bulk acoustic wave device including a first electrode, a second electrode, and a first aluminum nitride piezoelectric layer between the first electrode and the second electrode; and
a second substrate having a second bulk acoustic wave device mounted thereon, the second bulk acoustic wave device including a third electrode, a fourth electrode, and a second aluminum nitride piezoelectric layer between the third electrode and the fourth electrode, the first bulk acoustic wave device having an electromechanical coupling coefficient (kₜ²) different from an electromechanical coupling coefficient (kₜ²) of the second bulk acoustic wave device.

2. The wafer-level packaged module of claim 1 wherein the first aluminum nitride piezoelectric layer is doped with a dopant selected from the group of scandium (Sc), yttrium (Y), hafnium (Hf), zirconium (Zr), tantalum (Ta), magnesium (Mg), niobium (Nb), silicon (Si), and chromium (Cr).

3. The wafer-level packaged module of claim 2 wherein the second aluminum nitride piezoelectric layer is pure aluminum nitride.

4. The wafer-level packaged module of claim 2 wherein the second aluminum nitride piezoelectric layer is doped with a dopant selected from the group of boron (B), titanium (Ti), gallium (Ga), calcium (Ca), and vanadium (V).

5. The wafer-level packaged module of claim 1 wherein the second aluminum nitride piezoelectric layer is doped with a dopant selected from the group of boron (B), titanium (Ti), gallium (Ga), calcium (Ca), and vanadium (V).

6. The wafer-level packaged module of claim 5 wherein the first aluminum nitride piezoelectric layer is pure aluminum nitride.

7. The wafer-level packaged module of claim 1 wherein the first bulk acoustic wave device is mounted on a first surface of the first substrate and the second bulk acoustic wave device is mounted on a first surface of the second substrate, the first surface of the first substrate facing the first surface of the second substrate.

8. The wafer-level packaged module of claim 1 further comprising a third bulk acoustic wave device mounted on the first substrate, the third bulk acoustic wave device including a fifth electrode, a sixth electrode, and a third aluminum nitride piezoelectric layer between the fifth electrode and the sixth electrode, the third bulk acoustic wave device having substantially the same electromechanical coupling coefficient (kₜ²) as the first bulk acoustic wave device.

9. The wafer-level packaged module of claim 8 wherein the first aluminum nitride piezoelectric layer and the third aluminum nitride piezoelectric layer both include pure aluminum nitride, and the second aluminum nitride piezoelectric layer is doped with a dopant selected from the group of boron (B), titanium (Ti), gallium (Ga), calcium (Ca), and vanadium (V).

10. The wafer-level packaged module of claim 9 wherein the first aluminum nitride piezoelectric layer and the third aluminum nitride piezoelectric layer are doped with a dopant selected from the group of scandium (Sc), yttrium (Y), hafnium (Hf), zirconium (Zr), tantalum (Ta), magnesium (Mg), niobium (Nb), silicon (Si), and chromium (Cr).

11. The wafer-level packaged module of claim 10 wherein the second aluminum nitride piezoelectric layer is doped with a dopant selected from the group of boron (B), titanium (Ti), gallium (Ga), calcium (Ca), and vanadium (V).

12. The wafer-level packaged module of claim 10 wherein the second aluminum nitride piezoelectric layer is pure aluminum nitride.

13. The wafer-level packaged module of claim 8 further comprising a fourth bulk acoustic wave device mounted on the second substrate, the fourth bulk acoustic wave device including a seventh electrode, an eighth electrode, and a fourth aluminum nitride piezoelectric layer between the seventh electrode and the eighth electrode, the fourth bulk acoustic wave device having substantially the same electromechanical coupling coefficient (kₜ²) as the second bulk acoustic wave device.

14. An acoustic wave filter, comprising a wafer-level package module, the wafer-level package module including:
a first substrate having a first bulk acoustic wave resonator mounted thereon, the first bulk acoustic wave resonator including a first electrode, a second electrode, and a first aluminum nitride piezoelectric layer between the first electrode and the second electrode; and
a second substrate having a second bulk acoustic wave resonator mounted thereon, the second bulk acoustic wave resonator including a third electrode, a fourth electrode, and a second aluminum nitride piezoelectric layer between the third electrode and the fourth electrode, the first bulk acoustic wave resonator having an electromechanical coupling coefficient (kₜ²) different from an electromechanical coupling coefficient (kₜ²) of the second bulk acoustic wave resonator.

15. The acoustic wave filter of claim 14 wherein the first bulk acoustic wave resonator and the second bulk acoustic wave resonator are electrically coupled in parallel.

16. The acoustic wave filter of claim 14 wherein the first bulk acoustic wave resonator and the second bulk acoustic wave resonator are electrically coupled in series.

17. The acoustic wave filter of claim 14 wherein the acoustic wave filter is a ladder type filter, a hybrid-ladder type filter, or a lattice type filter.

18. A duplexer comprising a wafer-level package module, the wafer-level package module including:
a first substrate having a first bulk acoustic wave resonator mounted thereon, the first bulk acoustic wave resonator including a first electrode, a second electrode, and a first aluminum nitride piezoelectric layer between the first electrode and the second electrode; and
a second substrate having a second bulk acoustic wave resonator mounted thereon, the second bulk acoustic wave resonator including a third electrode, a fourth electrode, and a second aluminum nitride piezoelectric layer between the third electrode and the fourth electrode, the first bulk acoustic wave resonator having an electromechanical coupling coefficient (kₜ²) different from an electromechanical coupling coefficient (kₜ²) of the second bulk acoustic wave resonator.

19. The duplexer of claim 18 wherein the first bulk acoustic wave resonator is a series resonator, and the second bulk acoustic wave resonator is a shunt resonator.

20. The duplexer of claim 18 wherein the first aluminum nitride piezoelectric layer of the first bulk acoustic wave resonator is made from pure aluminum nitride.

21. The duplexer of claim 20 wherein the first aluminum nitride piezoelectric layer of the first bulk acoustic wave resonator is doped with a dopant selected from the group of boron (B), titanium (Ti), gallium (Ga), calcium (Ca), and vanadium (V).

22. The duplexer of claim 21 wherein the second aluminum nitride piezoelectric layer of the second bulk acoustic wave resonator is doped with a dopant selected from the group of scandium (Sc), yttrium (Y), hafnium (Hf), zirconium (Zr), tantalum (Ta), magnesium (Mg), niobium (Nb), silicon (Si), and chromium (Cr).
